(19) United States
(12) Patent Application Publication
(10) Pub. No.: US 2022/0385208 A1
(43) Pub. Date: Dec. 1, 2022

(54) POWER CONVERSION DEVICE AND MACHINE LEARNING DEVICE

(71) Applicant: Mitsubishi Electric Corporation, Tokyo (JP)

(72) Inventors: Daiki MATSUOKA, Tokyo (JP); Tatsuki MATSUNAGA, Tokyo (JP); Shizuri TAMURA, Tokyo (JP); Kiyofumi KITAI, Tokyo (JP); Shoji ADACHI, Tokyo (JP); Kosuke FUJIMOTO, Tokyo (JP)

(73) Assignee: Mitsubishi Electric Corporation, Tokyo (JP)

(21) Appl. No.: 17/767,052

(22) PCT Filed: Nov. 29, 2019
(86) PCT No.: PCT/JP2019/046703

§ 371 Date: Apr. 7, 2022

(51) Int. Cl. H02M 7/537; H02M 1/32; G01R 31/26

(52) U.S. Cl. CPC H02M 7/537; H02M 1/327; G01R 31/26

(57) ABSTRACT

A power conversion device including a switching element includes: a temperature change estimation unit estimating temperature change in a semiconductor chip containing the switching element; a number calculator calculating the number of power cycles to fracture of the semiconductor chip due to power cycles; and a degradation degree calculator computing a degree of degradation of the semiconductor chip caused by the power cycles. The temperature change estimation unit calculates a maximum value and a minimum value of temperature of the semiconductor chip in one power cycle based on a first threshold of temperature fall allowed when it is determined that the temperature of the semiconductor chip is rising, and a second threshold of temperature rise allowed when it is determined that the temperature of the semiconductor chip is falling. The number calculator calculates the number of power cycles to fracture based on the maximum value and the minimum value.

### FIELD

The present invention relates to a power conversion device and a machine learning device that compute the degree of degradation of a semiconductor chip including a switching element.

### BACKGROUND

Semiconductor power converters (hereinafter referred to as power converters) such as inverters have semiconductor switching elements (hereinafter referred to as switching elements). During the operation of a power converter, loss that occurs in the switching element causes an increase in the temperature of the switching element, and once the power converter stops, the temperature of the switching element decreases. This repetition of rise and fall in the temperature of the switching element, which is called power cycles, causes degradation (hereinafter referred to as power cycle degradation) of the semiconductor chip in which the switching element is located, shortening the life of the semiconductor chip.

A power conversion device including a power converter and a controller that controls the power converter can estimate power cycle degradation if the temperature change in the semiconductor chip, that is, junction temperature, is known. However, it is difficult for the power conversion device in practice to directly measure the junction temperature in the semiconductor chip. Therefore, the power conversion device predicts power cycle degradation, and predicts the life of the semiconductor chip associated with power cycles based on the prediction result.

The inverter protection device described in Patent Literature 1 computes a temperature fluctuation value, i.e. the difference between the peak value of temperature rise and the peak value of temperature fall in the switching element in one AC cycle, from the switching frequency of the power converter and the AC output current. The inverter protection device described in Patent Literature 1 estimates the level of power cycle degradation of the switching element from the temperature fluctuation value.

### CITATION LIST

### Patent Literature

Patent Literature 1: Japanese Patent Application Laid-open No. 2006-254574

### SUMMARY

### Technical Problem

However, in the technique of Patent Literature 1, if the output frequency of the power converter is low and the switching frequency of the power converter is set low, large pulsation (ripple) occurs in the output current during one cycle of the output frequency. The technique of Patent Literature 1, in which the temperature fluctuation corresponding to the switching element loss caused by the ripple cannot be considered, is problematic in terms of poor estimation accuracy of power cycle degradation.

The present invention has been made in view of the above, and an object thereof is to obtain a power conversion device capable of accurately estimating the level of power cycle degradation.

### Solution to Problem

In order to solve the above-described problems and achieve the object, the present invention provides a power conversion device including a switching element, the power conversion device including: a control unit that outputs a control signal to control the switching element; and a drive unit that drives the switching element based on the control signal. The power conversion device according to the present invention includes a temperature change estimation unit that estimates a temperature change in a semiconductor chip containing the switching element based on a current value flowing through the switching element and the control signal. The power conversion device according to the present invention includes a number calculation unit that calculates, based on the temperature change, the number of power cycles to fracture of the semiconductor chip due to power cycles applied to the semiconductor chip; and a degradation degree calculation unit that computes, based on the number of power cycles to fracture, a degree of degradation of the semiconductor chip caused by the power cycles as a degree of power cycle degradation. The temperature change estimation unit calculates a maximum value of a temperature of the semiconductor chip in one power cycle based on a first threshold and the temperature change, the first threshold being a threshold of temperature fall allowed when it is determined that the temperature of the semiconductor chip is rising. The temperature change estimation unit calculates a minimum value of the temperature of the semiconductor chip in one power cycle based on a second threshold and the temperature change, the second threshold being a threshold of temperature rise allowed when it is determined that the temperature of the semiconductor chip is falling. The number calculation unit calculates the number of power cycles to fracture based on the maximum value and the minimum value.

### Advantageous Effects of Invention

The power conversion device according to the present invention can achieve the effect of accurately estimating the level of power cycle degradation.

### BRIEF DESCRIPTION OF DRAWINGS

FIG. 1 is a diagram illustrating a configuration of a semiconductor module provided in a power conversion device according to a first embodiment.

FIG. 2 is a diagram for explaining the concept of a process of estimating the degree of power cycle degradation by the power conversion device according to the first embodiment.

FIG. 3 is a diagram illustrating a configuration of a power conversion system including the power conversion device according to the first embodiment.

FIG. 4 is a diagram illustrating a configuration of the power loss calculator provided in the power conversion device according to the first embodiment.

FIG. 5 is a diagram illustrating a configuration of the IGBT loss calculator provided in the power conversion device according to the first embodiment.

FIG. 6 is a diagram illustrating a configuration of the FWD loss calculator provided in the power conversion device according to the first embodiment.

FIG. 7 is a schematic diagram for explaining temporal changes in the thermal resistance value of the switching element.

FIG. 8 is a diagram illustrating a configuration of the chip temperature change calculator provided in the power conversion device according to the first embodiment.

FIG. 9 is a diagram illustrating another exemplary configuration of the chip temperature change calculator provided in the power conversion device according to the first embodiment.

FIG. 10 is a diagram illustrating a configuration of the temperature change calculator provided in the power conversion device according to the first embodiment.

FIG. 11 is a diagram illustrating a configuration of the rise maximum value computation unit provided in the power conversion device according to the first embodiment.

FIG. 12 is a flowchart illustrating a procedure for the operation of the rise maximum value computation unit provided in the power conversion device according to the first embodiment.

FIG. 13 is a diagram illustrating a configuration of the fall minimum value computation unit provided in the power conversion device according to the first embodiment.

FIG. 14 is a flowchart illustrating a procedure for the operation of the fall minimum value computation unit provided in the power conversion device according to the first embodiment.

FIG. 15 is a schematic diagram for explaining the number of lifetime power cycles with respect to the temperature fluctuation difference of the switching element.

FIG. 16 is a diagram illustrating another exemplary configuration of the power conversion system including the power conversion device according to the first embodiment.

FIG. 17 is a diagram for explaining the connection position of the current measuring instrument provided in the power conversion device illustrated in FIG. 16.

FIG. 18 is a diagram for explaining the connection position of the current measuring instrument connected to the collector side of the upper switching element of the semiconductor module provided in the power conversion device according to the first embodiment.

FIG. 19 is a diagram illustrating a configuration of a power conversion system including a power conversion device according to a second embodiment.

FIG. 20 is a diagram illustrating a configuration of the chip temperature change calculator provided in the power conversion device according to the second embodiment.

FIG. 21 is a diagram illustrating another exemplary configuration of the chip temperature change calculator provided in the power conversion device according to the second embodiment.

FIG. 22 is a diagram illustrating a configuration of a power conversion system including a power conversion device according to a third embodiment.

FIG. 23 is a diagram illustrating a configuration of the current estimation unit provided in the power conversion device according to the third embodiment.

FIG. 24 is a diagram for explaining a procedure for learning processing and utilization processing by the power conversion device according to the third embodiment.

FIG. 25 is a diagram illustrating a configuration of a neural network that is used by the machine learning device according to the third embodiment.

FIG. 26 is a diagram illustrating an exemplary hardware configuration that implements the current estimation unit provided in the power conversion device according to the third embodiment.

### DESCRIPTION OF EMBODIMENTS

Hereinafter, a power conversion device and a machine learning device according to embodiments of the present invention will be described in detail with reference to the drawings. The present invention is not limited to the embodiments.

### First Embodiment

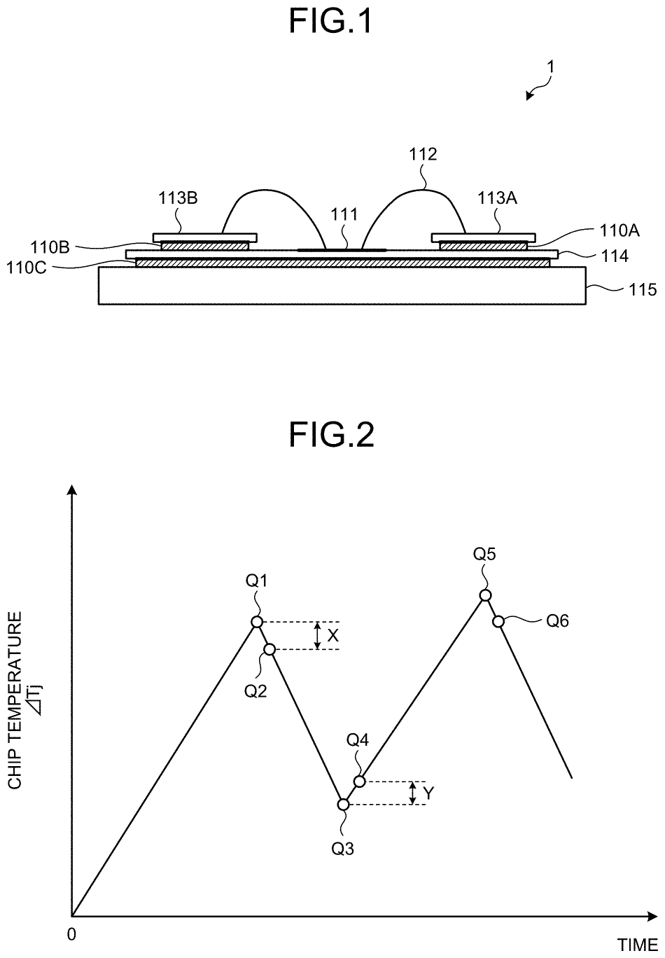

FIG. 1 is a diagram illustrating a configuration of a semiconductor module provided in a power conversion device according to a first embodiment. The following description refers to a case where the power conversion device includes a power semiconductor module (hereinafter referred to as a semiconductor module) 1 incorporating a switching element (semiconductor switching element), and the semiconductor module 1 includes an insulated gate bipolar transistor (IGBT) and a freewheel diode (FWD) as the switching element.

The semiconductor module 1 includes a substrate 114 coated with a circuit pattern 111. On the substrate 114, a semiconductor chip 113A is soldered with solder 110A, and a semiconductor chip 113B is soldered with solder 110B.

The semiconductor chip 113A, or a first chip, contains an IGBT, and the semiconductor chip 113B, or a second chip, contains an FWD. Note that multiple sets of semiconductor chips 113A and 113B may be arranged in the semiconductor module 1.

The semiconductor module 1 includes a wire 112 bonded to the circuit pattern 111 and the semiconductor chips 113A and 113B using ultrasonic waves. The substrate 114 is soldered to a base plate 115 with solder 110C. Hereinafter, a configuration of the power conversion device, a method of estimating a temperature change in a switching element in the power conversion device, a method of estimating the degree of power cycle degradation, and a method of estimating the life (hereinafter referred to as the power cycle life) of the semiconductor chips 113A and 113B associated with power cycles will be described. The power conversion device (power conversion device 200A described later) according to the present embodiment estimates a temperature change in the semiconductor chips 113A and 113B containing a switching element as a temperature change in the switching element.

FIG. 2 is a diagram for explaining the concept of a process of estimating the degree of power cycle degradation by the power conversion device according to the first embodiment. In the graph illustrated in FIG. 2, the horizontal axis represents time, and the vertical axis represents the chip temperature.

The power conversion device 200A according to the present embodiment estimates the temperature of the semiconductor chips 113A and 113B (hereinafter also referred to as chip temperature) based on the current flowing through the semiconductor module 1. Further, the power conversion device 200A estimates the degree of degradation of the switching element (degree of power cycle degradation) caused by power cycles based on a change in chip temperature. Specifically, the power conversion device 200A estimates the degree of power cycle degradation caused by the power cycles of the IGBT based on a change in the chip temperature of the semiconductor chip 113A containing the IGBT, and estimates the degree of power cycle degradation caused by the power cycles of the FWD based on a change in the chip temperature of the semiconductor chip 113B containing the FWD.

The chip temperature repeatedly rises and falls over time. After the power conversion device 200A is activated, the chip temperature rises; then the power conversion device 200A updates the maximum value of the chip temperature in one power cycle (maximum value ΔTjmax of chip temperature rise described later).

For example, suppose that the chip temperature rises until timing Q1 and then falls. In this case, once the chip temperature falls by a specific temperature (rise change threshold X described later) at timing Q2 from the chip temperature at timing Q1, the power conversion device 200A sets the chip temperature at timing Q1 as the maximum value ΔTjmax of chip temperature rise in one power cycle.

The chip temperature falls after timing Q2; then the power conversion device 200A updates the minimum value of the chip temperature in this power cycle (minimum value ΔTjmin of chip temperature fall described later). Suppose that after timing Q2, the chip temperature falls until timing Q3 and then rises. In this case, once the chip temperature rises by a specific temperature (fall change threshold Y described later) at timing Q4 from the chip temperature at timing Q3, the power conversion device 200A sets the chip temperature at timing Q3 as the minimum value ΔTjmin of chip temperature fall in this power cycle.

Further, suppose that after timing Q4, the chip temperature rises until timing Q5 and then falls. In this case, once the chip temperature falls by a specific temperature at timing Q6 from the chip temperature at timing Q5, the power conversion device 200A sets the chip temperature at timing Q5 as the maximum value ΔTjmax of chip temperature rise in this power cycle. The power conversion device 200A repeats the process of setting the maximum value ΔTjmax of chip temperature rise and the minimum value ΔTjmin of chip temperature fall in each power cycle.

The power conversion device 200A computes the difference between the chip temperature at timing Q1 and the chip temperature at timing Q3, that is, the difference between the maximum value and the minimum value of the chip temperature in one power cycle (temperature fluctuation difference ΔTj (max−min) described later), and estimates the degree of degradation of the switching element based on the difference. In this manner, in the present embodiment, the process of estimating the degree of degradation of the switching element is repeated not for every cycle of the output frequency of the power conversion device 200A but for every difference between the maximum value ΔTjmax of chip temperature rise and the minimum value ΔTjmin of chip temperature fall in one power cycle.

The power conversion device 200A separately estimates the degree of power cycle degradation of the semiconductor chip 113A containing the IGBT and the degree of power cycle degradation of the semiconductor chip 113B containing the FWD. Note that the IGBT and the FWD may be contained in one semiconductor chip, in which case the power conversion device 200A estimates the degree of power cycle degradation of the semiconductor chip containing the IGBT and the FWD.

In this manner, the power conversion device 200A is configured to compute, as the temperature fluctuation in one power cycle, a fall of a threshold or more from the peak value of temperature rise in the semiconductor chips 113A and 113B and a rise of a threshold or more from the peak value of temperature fall. This enables the power conversion device 200A to deal with a situation where large pulsation (ripple) occurs in the output current during one cycle of the output frequency by computing the temperature fluctuation corresponding to the switching element loss caused by the ripple as the temperature fluctuation in one power cycle. Therefore, the power conversion device 200A can accurately estimate the level of power cycle degradation.

In the following description, the degree of power cycle degradation of the semiconductor chip 113A may be referred to as the degree of power cycle degradation of the IGBT. Similarly, the degree of power cycle degradation of the semiconductor chip 113B may be referred to as the degree of power cycle degradation of the FWD.

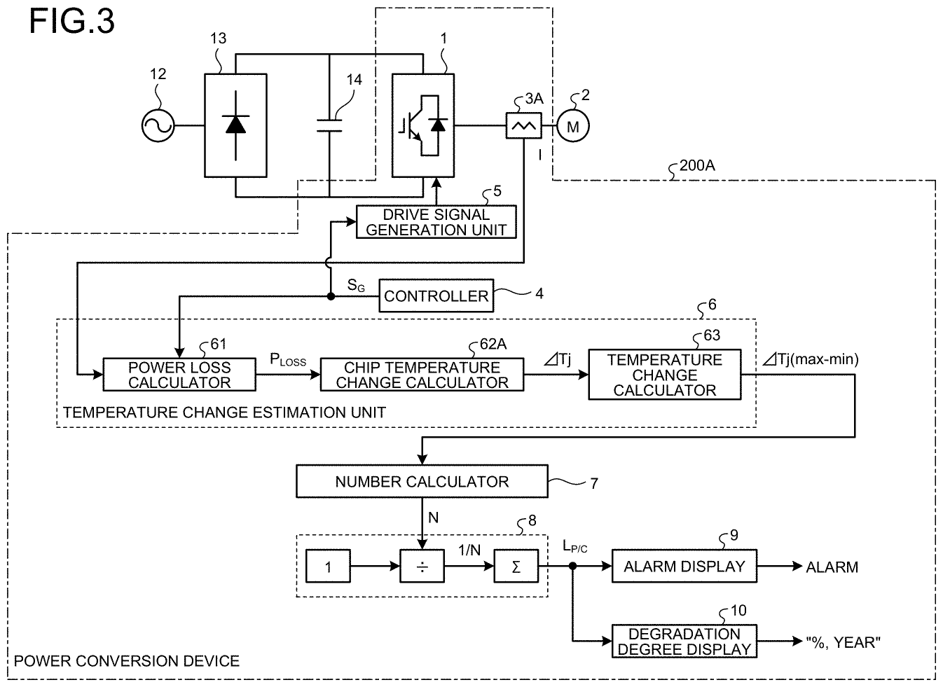

FIG. 3 is a diagram illustrating a configuration of a power conversion system including the power conversion device according to the first embodiment. The power conversion system includes a commercial power supply 12, a converter circuit 13, a smoothing capacitor 14, the power conversion device 200A, and a motor 2.

The power conversion device 200A estimates a temperature change in the semiconductor chips 113A and 113B containing the switching element based on a current value I flowing through the switching element and a control signal S_{G} for controlling the switching element. The power conversion device 200A calculates the number of power cycles to fracture of the semiconductor chips 113A and 113B due to power cycles based on the temperature change, and computes the degree of degradation of the semiconductor chips 113A and 113B caused by power cycles based on the number of power cycles to fracture. The power conversion device 200A separately estimates the degree of degradation of the semiconductor chip 113A and the degree of degradation of the semiconductor chip 113B.

The power conversion device 200A includes the semiconductor module 1 including the switching element, a current measuring instrument 3A, a controller 4, a drive signal generation unit 5, and a temperature change estimation unit 6. The power conversion device 200A also includes a number calculator 7, a degradation degree calculator 8, an alarm display 9, and a degradation degree display 10. Note that the alarm display 9 and the degradation degree display 10 may be configured separately from the power conversion device 200A.

An example of the semiconductor module 1 is an inverter circuit. The semiconductor module 1 is connected to the commercial power supply 12 via the smoothing capacitor 14 and the converter circuit 13. The semiconductor module 1 is also connected to the motor 2 and the drive signal generation unit 5.

In the power conversion system, the semiconductor module 1, the converter circuit 13, and the smoothing capacitor 14 constitute a motor drive device. The motor drive device receives AC power supply from the commercial power supply 12 to drive the motor 2.

The converter circuit 13 rectifies the AC voltage applied from the commercial power supply 12 to convert the AC voltage into a DC voltage. An example of the converter circuit 13 is a full-wave rectifier circuit including a diode bridge. The smoothing capacitor 14 is connected to two DC buses connecting the converter circuit 13 and the semiconductor module 1. The smoothing capacitor 14 smooths the bus voltage.

The semiconductor module 1 operates in accordance with a drive signal sent from the drive signal generation unit 5. The semiconductor module 1 converts the DC voltage smoothed by the smoothing capacitor 14 into an AC voltage and applies the AC voltage to the motor 2 to drive the motor 2.

The semiconductor module 1 includes the switching element. The switching element provided in the semiconductor module 1 includes an IGBT and an FWD. In the semiconductor module 1, the IGBT and the FWD are reversely connected.

The current measuring instrument 3A is connected to the connection line connecting the semiconductor module 1 and the motor 2. The current measuring instrument 3A measures the current flowing through the switching element by measuring the current flowing between the semiconductor module 1 and the motor 2. The current measuring instrument 3A sends the current value I as the measurement result to the temperature change estimation unit 6.

Note that the current measuring instrument 3A only needs to be able to measure the current flowing through the switching element. Therefore, the present embodiment is not limited by the form of the current measuring instrument 3A. The current measuring instrument 3A includes, for example, a current transformer (CT), a resistor, or the like.

The controller 4, or a control unit, generates the control signal S_{G} for controlling the switching element located in the semiconductor module 1, and sends the control signal S_{G} to the drive signal generation unit 5. The controller 4 also sends the control signal S_{G} to the temperature change estimation unit 6.

The drive signal generation unit 5, or a drive unit, drives the switching element located in the semiconductor module 1 based on the control signal S_{G}. The drive signal generation unit 5 generates a drive signal for driving the semiconductor module 1 based on the control signal S_{G}, and inputs the drive signal to the semiconductor module 1.

The temperature change estimation unit 6 estimates the temperature fluctuation difference ΔTj (max−min) of the switching element in the semiconductor chips 113A and 113B based on the current value I, which is a measured value of the current flowing through the switching element, and the control signal S_{G} input from the controller 4. The temperature fluctuation difference ΔTj (max−min) is the difference between the maximum value and the minimum value of the temperature of the switching element in one power cycle. The temperature change estimation unit 6 sends the temperature fluctuation difference ΔTj (max−min) to the number calculator 7.

The temperature change estimation unit 6 includes a power loss calculator 61, a chip temperature change calculator 62A, and a temperature change calculator 63. The power loss calculator 61 calculates a power loss generated in the switching element based on the current value I measured by the current measuring instrument 3A and the control signal S_{G} input from the controller 4. The temperature change estimation unit 6 calculates a power loss (power loss P_{IGBT} described later) generated in the IGBT and a power loss (power loss P_{FWD} described later) generated in the FWD. The power loss calculator 61 sends the calculated power loss to the chip temperature change calculator 62A. In FIG. 3, the power loss sent from the power loss calculator 61 to the chip temperature change calculator 62A is indicated by power loss P_{Loss}. The power loss P_{Loss} is the power loss P_{IGBT} and the power loss P_{FWD}.

The chip temperature change calculator 62A calculates a chip temperature change in the semiconductor chips 113A and 113B containing the switching element based on the power loss generated in the switching element. That is, the temperature change estimation unit 6 separately calculates a chip temperature change ΔTj in the IGBT and a chip temperature change ΔTj in the FWD. The chip temperature change ΔTj in the IGBT is a temperature change in the semiconductor chip 113A, and the chip temperature change ΔTj in the FWD is a temperature change in the semiconductor chip 113B.

Based on the transition of the chip temperature change ΔTj, the temperature change calculator 63 calculates the difference between the maximum value ΔTjmax of chip temperature rise and the minimum value ΔTjmin of chip temperature fall in one power cycle as the temperature fluctuation difference ΔTj (max−min). The temperature change calculator 63 calculates the temperature fluctuation difference ΔTj (max−min) of the IGBT and the temperature fluctuation difference ΔTj (max−min) of the FWD.

The number calculator 7, or a number calculation unit, converts the power cycle degradation of the switching element into the number of lifetime power cycles N, i.e. the number of power cycles to fracture, based on the temperature fluctuation difference ΔTj (max−min). The number calculator 7 computes the number of lifetime power cycles N corresponding to the temperature fluctuation difference ΔTj (max−min) based on power cycle life data prepared in advance. The power cycle life data are data in which the temperature fluctuation difference ΔTj (max−min) and the number of lifetime power cycles N are associated with each other. The number of lifetime power cycles N is the number of power cycles to fracture of the semiconductor chips 113A and 113B including the switching element due to power cycles (thermal fatigue). The number calculator 7 separately calculates the number of lifetime power cycles N for the IGBT and the number of lifetime power cycles N for the FWD. The number calculator 7 sends the number of lifetime power cycles N to the degradation degree calculator 8.

The degradation degree calculator 8, or a degradation degree calculation unit, calculates a degree of power cycle degradation L_{P/C} of the switching element by accumulating the number of lifetime power cycles N obtained through conversion. Specifically, the degradation degree calculator 8 computes the ratio of the number of lifetime power cycles N to the power cycle life as 1/N, and accumulates the computed ratio to the power cycle life to calculate the degree of power cycle degradation L_{P/C}. The degradation degree calculator 8 calculates the degree of power cycle degradation L_{P/C} of the IGBT and the degree of power cycle degradation L_{P/C} of the FWD. The degradation degree calculator 8 sends the degree of power cycle degradation L_{P/C} to the alarm display 9 and the degradation degree display 10.

The alarm display 9 displays an alarm when the degree of power cycle degradation L_{P/C} exceeds a reference value. The alarm display 9 compares a preset alarm level (reference value) with the degree of power cycle degradation L_{P/C}, and displays an alarm when the degree of power cycle degradation L_{P/C} exceeds the alarm level. The degradation degree display 10 displays the degree of power cycle degradation L_{P/C}. The degree of power cycle degradation L_{P/C} is represented by the progress (%) of degradation to the life, the period (number of years) to the life, or the like.

Note that the present embodiment describes a case where the semiconductor module 1 includes an IGBT as a switching element, but the switching element is not limited to the IGBT. The switching element may be a metal-oxide-semiconductor field-effect transistor (MOSFET), for example.

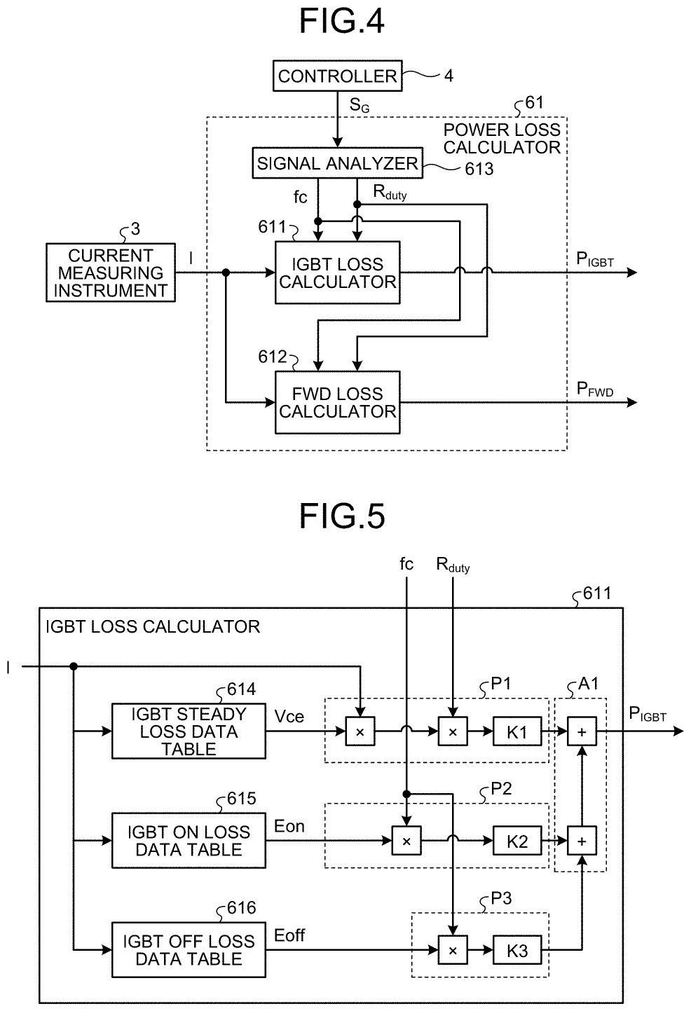

FIG. 4 is a diagram illustrating a configuration of the power loss calculator provided in the power conversion device according to the first embodiment. The power loss calculator 61 includes an IGBT loss calculator 611, an FWD loss calculator 612, and a signal analyzer 613.

The signal analyzer 613 calculates and outputs, based on the control signal S_{G} input from the controller 4, information necessary for the calculation of the power loss P_{IGBT} generated in the IGBT. Specifically, the signal analyzer 613 calculates a switching frequency fc of the IGBT and a duty ratio R_{duty} of the IGBT as information necessary for the calculation of the power loss P_{IGBT}, and outputs the information to the IGBT loss calculator 611. The duty ratio R_{duty} of the IGBT is the ratio between the on time and the off time during the switching of the IGBT.

In addition, the signal analyzer 613 calculates and outputs, based on the control signal S_{G} input from the controller 4, information necessary for the calculation of the power loss P_{FWD} generated in the FWD. Specifically, the signal analyzer 613 calculates the switching frequency fc of the FWD and the duty ratio R_{duty} of the FWD as information necessary for the calculation of the power loss P_{FWD}, and outputs the information to the FWD loss calculator 612. The duty ratio R_{duty} of the FWD is the ratio between the on time and the off time during the switching of the FWD.

The duty ratio R_{duty} is a value for setting the period in which the switching element is on or off with respect to the cycle of the switching frequency fc. Therefore, the IGBT loss calculator 611 and the FWD loss calculator 612 can identify the period in which the current flows through the IGBT of the switching element and the period in which the current flows through the FWD of the switching element based on the duty ratio R_{duty} and the current value I measured by the current measuring instrument 3A.

The IGBT loss calculator 611 calculates the power loss P_{IGBT} in the IGBT of the switching element based on the current value I input from the current measuring instrument 3A, the switching frequency fc of the IGBT, and the duty ratio R_{duty} of the IGBT.

In a similar manner to the IGBT loss calculator 611, the FWD loss calculator 612 calculates the power loss P_{FWD} in the FWD of the switching element based on the current value I input from the current measuring instrument 3A, the switching frequency fc of the FWD, and the duty ratio R_{duty} of the FWD.

In this manner, the power loss calculator 61 computes the power loss P_{IGBT} in the IGBT with the IGBT loss calculator 611, and computes the power loss P_{FWD} in the FWD with the FWD loss calculator 612.

The IGBT loss calculator 611 outputs the power loss P_{IGBT} to the chip temperature change calculator 62A. The FWD loss calculator 612 outputs the power loss P_{FWD} to the chip temperature change calculator 62A.

FIG. 5 is a diagram illustrating a configuration of the IGBT loss calculator provided in the power conversion device according to the first embodiment. The IGBT loss calculator 611 includes an IGBT steady loss data table 614, an IGBT on loss data table 615, an IGBT off loss data table 616, calculators P1 to P3, and an adder A1.

The IGBT steady loss data table 614 stores the loss characteristics of the IGBT in the steady state. In the IGBT steady loss data table 614, the current value I is associated with a voltage Vce generated when the current value I is applied to the IGBT. Based on the IGBT steady loss data table 614 and the current value I in the steady state measured by the current measuring instrument 3A, the IGBT loss calculator 611 calculates the voltage Vce generated when the current value I is applied to the IGBT, and sends the voltage Vce to the calculator P1.

The IGBT on loss data table 615 stores the loss characteristics of the IGBT in the on state. In the IGBT on loss data table 615, the current value I in the case that the IGBT transitions from the off state to the on state is associated with a turn-on energy Eon of the IGBT generated when the IGBT transitions from the off state to the on state. Based on the IGBT on loss data table 615 and the current value I generated when the IGBT transitions from the off state to the on state, the IGBT loss calculator 611 calculates the turn-on energy Eon of the IGBT with respect to the current value I, and sends the turn-on energy Eon to the calculator P2.

The IGBT off loss data table 616 stores the loss characteristics of the IGBT in the off state. In the IGBT off loss data table 616, the current value I in the case that the IGBT transitions from the on state to the off state is associated with a turn-off energy Eoff of the IGBT generated when the IGBT transitions from the on state to the off state. Based on the IGBT off loss data table 616 and the current value I generated when the IGBT transitions from the on state to the off state, the IGBT loss calculator 611 calculates the turn-off energy Eoff of the IGBT with respect to the current value I, and sends the turn-off energy Eoff to the calculator P3.

The calculator P1 multiplies the current value I in the steady state of the IGBT, the voltage Vce, the duty ratio R_{duty} of the IGBT, and a first coefficient K1, and sends the result to the adder A1.

The calculator P2 multiplies the turn-on energy Eon of the IGBT, the switching frequency fc of the IGBT, and a second coefficient K2, and sends the result to the adder A1.

The calculator P3 multiplies the turn-off energy Eoff of the IGBT, the switching frequency fc of the IGBT, and a third coefficient K3, and sends the result to the adder A1.

The adder A1 adds up the values sent from the calculators P1, P2, and P3 to compute the power loss P_{IGBT} in the IGBT. That is, the IGBT loss calculator 611 computes the power loss P_{IGBT} in the IGBT using Formula (1) below.

[Formula 1]

P_{IGBT}=K1×(I×Vce×R_{duty})+K2×(Eon×fc)+K3×(Eoff×fc) (1)

Here, any value can be set as the first coefficient K1, the second coefficient K2, and the third coefficient K3 as long as the value has a positive sign. The adder A1 outputs the power loss P_{IGBT} in the IGBT to the chip temperature change calculator 62A.

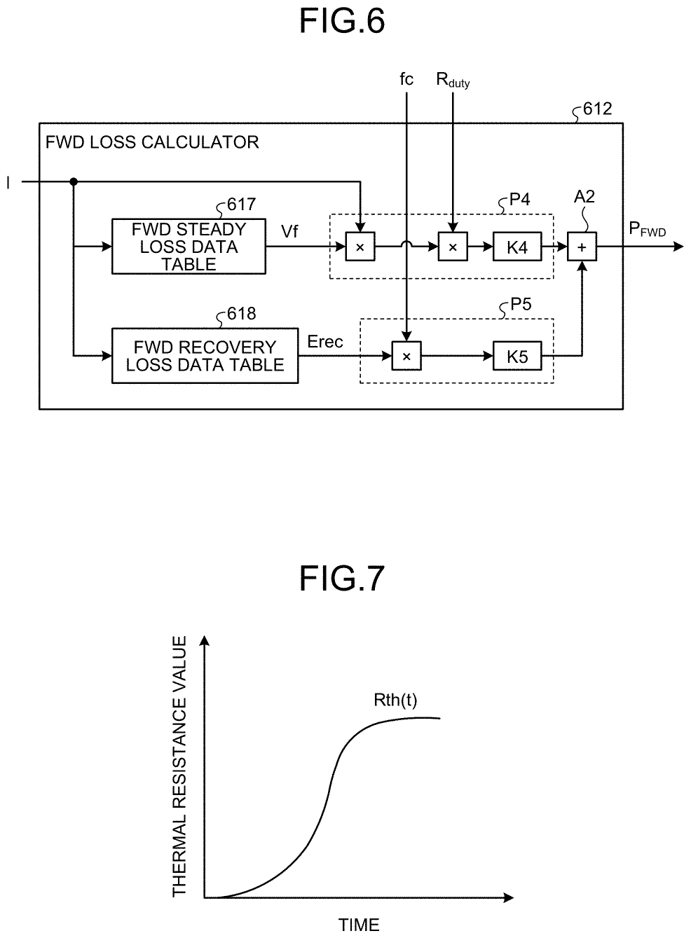

FIG. 6 is a diagram illustrating a configuration of the FWD loss calculator provided in the power conversion device according to the first embodiment. The FWD loss calculator 612 includes an FWD steady loss data table 617, an FWD recovery loss data table 618, calculators P4 and P5, and an adder A2.

The FWD steady loss data table 617 stores the loss characteristics of the FWD in the steady state. In the FWD steady loss data table 617, the current value I is associated with a voltage Vf generated when the current value I is applied to the FWD. Based on the FWD steady loss data table 617 and the current value I in the steady state measured by the current measuring instrument 3A, the FWD loss calculator 612 calculates the voltage Vf generated when the current value I is applied to the FWD, and sends the voltage Vf to the calculator P4.

The FWD recovery loss data table 618 stores the recovery loss characteristics of the FWD. In the FWD recovery loss data table 618, the current value I is associated with a turn-on energy Erec of the FWD generated due to the recovery characteristics of the FWD with respect to the current value I. Based on the FWD recovery loss data table 618 and the current value I in the recovery state measured by the current measuring instrument 3A, the FWD loss calculator 612 calculates the turn-on energy Erec of the FWD with respect to the current value I in the recovery state, and sends the turn-on energy Erec to the calculator P5.

The calculator P4 multiplies the current value I in the steady state of the FWD, the voltage Vf, the duty ratio R_{duty} of the FWD, and a fourth coefficient K4, and sends the result to the adder A2.

The calculator P5 multiplies the turn-on energy Erec of the FWD, the switching frequency fc of the FWD, and a fifth coefficient K5, and sends the result to the adder A2.

The adder A2 adds up the values sent from the calculators P4 and P5 to compute the power loss P_{FWD} in the FWD. That is, the FWD loss calculator 612 computes the power loss P_{FWD} in the FWD using Formula (2) below.

[Formula 2]

P_{FWD}=K4×(I×Vf×R_{duty})+K5×(Erec×fc) (2)

Here, any value can be set as the fourth coefficient K4 and the fifth coefficient K5 as long as the value has a positive sign. The adder A2 outputs the power loss P_{FWD} in the FWD to the chip temperature change calculator 62A.

The chip temperature change calculator 62A stores data of a transient thermal resistance Rth(t) of the IGBT and data of a transient thermal resistance Rth(t) of the FWD. The data of the transient thermal resistance Rth(t) are data indicating temporal changes in the thermal resistance value of the switching element.

The chip temperature change calculator 62A calculates the chip temperature change ΔTj in the semiconductor chip 113A containing the IGBT based on the data of the transient thermal resistance Rth(t) of the IGBT and the power loss P_{IGBT} computed by the power loss calculator 61. The chip temperature change calculator 62A calculates the chip temperature change ΔTj in the semiconductor chip 113B containing the FWD based on the data of the transient thermal resistance Rth(t) of the FWD and the power loss P_{FWD} computed by the power loss calculator 61. The chip temperature change calculator 62A outputs the chip temperature change ΔTj in the IGBT and the chip temperature change ΔTj in the FWD to the temperature change calculator 63.

FIG. 7 is a schematic diagram for explaining temporal changes in the thermal resistance value of the switching element. FIG. 7 shows the relationship between the thermal resistance value of the switching element and time, that is, data of the transient thermal resistance Rth(t). In FIG. 7, the horizontal axis represents time, and the vertical axis represents the thermal resistance value.

As illustrated in FIG. 7, the thermal resistance value of the switching element changes with the lapse of time, and is not a constant value. The thermal resistance corresponding to the lapse of time is the transient thermal resistance Rth(t).

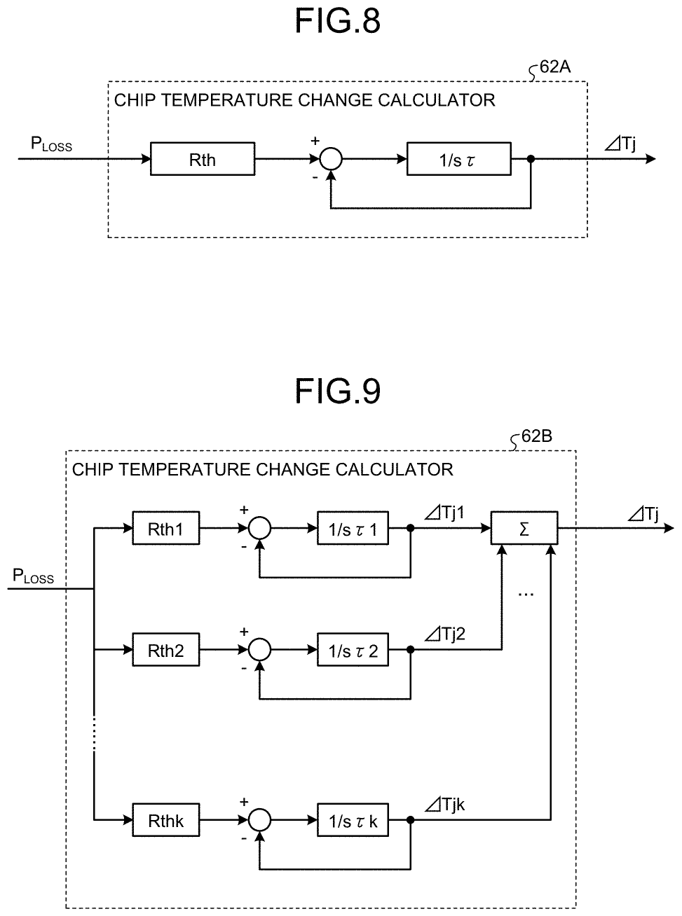

FIG. 8 is a diagram illustrating a configuration of the chip temperature change calculator provided in the power conversion device according to the first embodiment. The chip temperature change calculator 62A includes thermal resistance data Rth and data of a first-order lag term 1/sτ in which the thermal time constant of the switching element is used, and expresses the transient thermal resistance by the heat transfer function of the first-order lag system using the sum of the thermal resistance data Rth and the first-order lag term 1/sτ. Here, the heat transfer function of the first-order lag system is expressed by Formula (3) below using the thermal resistance (Rth), the thermal time constant (τ), and the Laplace operator (s). Note that the actual transient thermal resistance Rth(t) gradually increases at first, then rapidly increases, and finally saturates to a constant value, as illustrated in FIG. 7.

$$[ Formula 3 ]$$

$$Rth ( t ) = Rth + \frac{1}{1 + s τ} \qquad ( 3 )$$

The chip temperature change calculator 62A computes the chip temperature change ΔTj using the power loss P_{Loss} generated in the switching element computed by the power loss calculator 61 and the transient thermal resistance Rth(t) that is based on Formula (3). The method of computing the chip temperature change ΔTj will be described later.

FIG. 9 is a diagram illustrating another exemplary configuration of the chip temperature change calculator provided in the power conversion device according to the first embodiment. The temperature change estimation unit 6 may include a chip temperature change calculator 62B, instead of the chip temperature change calculator 62A. FIG. 9 illustrates the configuration of the chip temperature change calculator 62B to be applied for high-accuracy simulation of the transient thermal resistance Rth(t).

The chip temperature change calculator 62B expresses the transient thermal resistance Rth(t) by the sum of a plurality of heat transfer functions of a plurality of first-order lag systems. In FIG. 9, the first piece of thermal resistance data is represented by thermal resistance data Rth1, and the k-th (k is a natural number of two or more) piece of thermal resistance data is represented by thermal resistance data Rthk. In FIG. 9, the first thermal time constant τ is represented by T1, and the k-th thermal time constant τ is represented by τk. In the chip temperature change calculator 62B, because the transient thermal resistance Rth(t) is expressed by the sum of the heat transfer functions of the first to k-th first-order lag systems, the transient thermal resistance Rth(t) can be expressed precisely. In the case of the chip temperature change calculator 62B, the transient thermal resistance Rth(t) is expressed by Formula (4) below.

$$[ Formula 4 ]$$

$$Rth ( t ) = {\sum }_{n = 1}^{k} \frac{Rthn}{1 + s τ n} \qquad ( 4 )$$

By increasing the number of heat transfer functions to be added in Formula (4), it is possible to express the transient thermal resistance Rth(t) with higher accuracy.

The chip temperature change calculator 62A can compute the chip temperature change ΔTj with Formula (5) below using the power loss P_{Loss} generated in the switching element computed by the power loss calculator 61 and the transient thermal resistance Rth(t) that is based on Formula (3).

Note that the chip temperature change calculator 62B may compute the chip temperature change ΔTj with Formula (5) below using the power loss P_{Loss} generated in the switching element computed by the power loss calculator 61 and the transient thermal resistance Rth(t) that is based on Formula (4).

[Formula 5]

ΔTj=Rth(t)×P_{Loss} (5)

P_{Loss} in Formula (5) is the power loss P_{IGBT} or the power loss P_{FWD}. The operation of the chip temperature change calculators 62A and 62B will be described in detail using Formula (5). Note that the chip temperature change calculators 62A and 62B operate similarly, and thus the operation of the chip temperature change calculator 62A will be described below.

The chip temperature change calculator 62A computes the chip temperature change ΔTj_IGBT in the IGBT using the transient thermal resistance Rth(t)_IGBT of the IGBT, the power loss P_{IGBT} in the IGBT, and Formula (6) below.

[Formula 6]

ΔTj_IGBT=Rth(t)_IGB T×P_{IGBT} (6)

In addition, the chip temperature change calculator 62A computes the chip temperature change ΔTj FWD in the FWD using the transient thermal resistance Rth(t) FWD of the FWD, the power loss P_{FWD} in the FWD, and Formula (7) below.

[Formula 7]

ΔTj_FWD=Rth(t)_FWD×P_{FWD} (7)

The chip temperature change calculator 62A substitutes the power loss P_{IGBT} in the IGBT or the power loss P_{FWD} in the FWD for the power loss P_{Loss} in Formula (5). In addition, the chip temperature change calculator 62A substitutes the transient thermal resistances Rth(t)_IGBT of the IGBT or the transient thermal resistance Rth(t) FWD of the FWD for the transient thermal resistance Rth(t) in Formula (5). Through these substitutions, the chip temperature change calculator 62A is able to compute each of the chip temperature change ΔTj_IGBT in the IGBT and the chip temperature change ΔTj FWD in the FWD for output to the temperature change calculator 63.

However, the present embodiment does not exclude the form in which either the chip temperature change ΔTj_IGBT in the IGBT or the chip temperature change ΔTj FWD in the FWD is selected and output. For example, the chip temperature change calculator 62A can output the result of computation based on Formula (6) as the chip temperature change ΔTj_IGBT so that the power conversion device 200A estimates the power cycle life of only the IGBT.

Returning to FIG. 3, the temperature change calculator 63 will be described. The temperature change calculator 63 computes the temperature fluctuation difference ΔTj (max−min) of the switching element based on the chip temperature change ΔTj input from the chip temperature change calculator 62A.

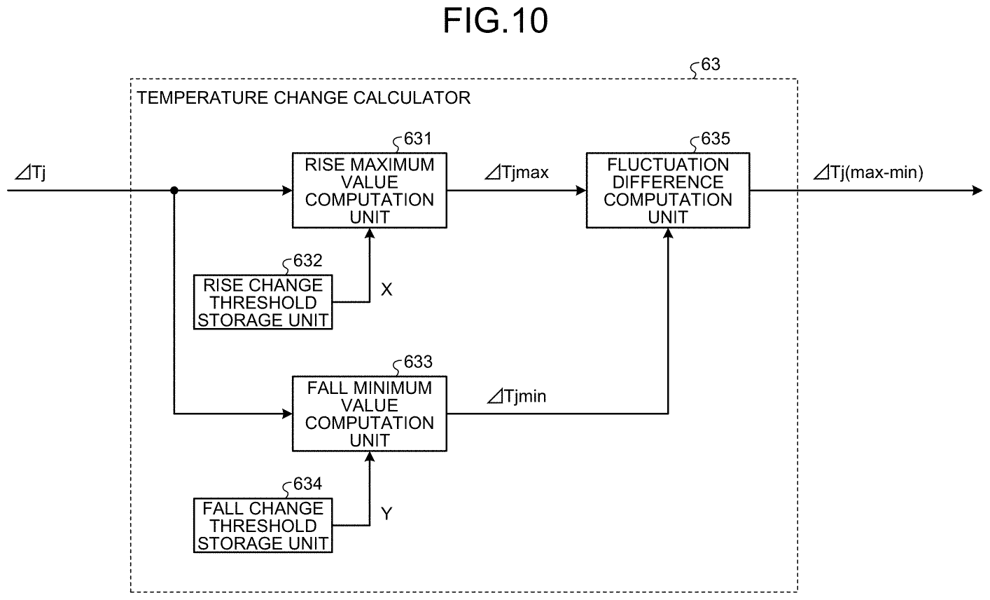

FIG. 10 is a diagram illustrating a configuration of the temperature change calculator provided in the power conversion device according to the first embodiment. The temperature change calculator 63 includes a rise maximum value computation unit 631, a rise change threshold storage unit 632, a fall minimum value computation unit 633, a fall change threshold storage unit 634, and a fluctuation difference computation unit 635.

The rise change threshold storage unit 632 stores the rise change threshold X as a first threshold, and the rise change threshold X is read by the rise maximum value computation unit 631. The rise change threshold X is a threshold for determining whether the chip temperature has a maximum value while the chip temperature is rising. Specifically, the rise change threshold X is a threshold of temperature fall allowed when it is determined that the temperature of the semiconductor chips 113A and 113B is rising. The rise change threshold storage unit 632 stores the rise change threshold X for the semiconductor chip 113A and the rise change threshold X for the semiconductor chip 113B.

While the chip temperature is rising, once the chip temperature falls by more than the rise change threshold X from the maximum value of the chip temperature in the current power cycle, the rise maximum value computation unit 631 sets the maximum value of the chip temperature in this power cycle as the current maximum value ΔTjmax of chip temperature rise. For example, in a case where the current maximum value of the chip temperature is T1 and the rise change threshold X is T2, once the chip temperature falls below T1−T2, the rise maximum value computation unit 631 determines that the maximum value ΔTjmax of chip temperature rise in this power cycle is T1.

On the other hand, while the chip temperature is rising, as long as the chip temperature falls only within the range of the rise change threshold X from the maximum value of the chip temperature in the current power cycle, the rise maximum value computation unit 631 determines that the chip temperature fall is within the error range. In this case, the rise maximum value computation unit 631 determines that the chip temperature has been rising, and updates the maximum value ΔTjmax of chip temperature rise in the current power cycle.

In this manner, the rise maximum value computation unit 631 computes the maximum value ΔTjmax of chip temperature rise based on the rise change threshold X stored in the rise change threshold storage unit 632, and outputs the maximum value ΔTjmax to the fluctuation difference computation unit 635. This maximum value ΔTjmax of chip temperature rise is the peak value (maximal value) of chip temperature rise in the switching element.

The maximum value ΔTjmax of chip temperature rise is the maximum value of the temperature of the semiconductor chips 113A and 113B in one power cycle. The rise maximum value computation unit 631 computes the maximum value ΔTjmax of chip temperature rise in the semiconductor chip 113A and the maximum value ΔTjmax of chip temperature rise in the semiconductor chip 113B.

Similarly, the fall change threshold storage unit 634 stores the fall change threshold Y as a second threshold, and the fall change threshold Y is read by the fall minimum value computation unit 633. The fall change threshold Y is a threshold for determining whether the chip temperature has a minimum value while the chip temperature is falling. Specifically, the fall change threshold Y is a threshold of temperature rise allowed when it is determined that the temperature of the semiconductor chips 113A and 113B is falling. The fall change threshold storage unit 634 stores the fall change threshold Y for the semiconductor chip 113A and the fall change threshold Y for the semiconductor chip 113B.

While the chip temperature is falling, once the chip temperature rises by more than the fall change threshold Y from the minimum value ΔTjmin of chip temperature fall in the current power cycle, the fall minimum value computation unit 633 sets the minimum value of the chip temperature in this power cycle as the minimum value ΔTjmin of chip temperature fall. For example, in a case where the current minimum value of the chip temperature is T3 and the fall change threshold Y is T4, once the chip temperature exceeds T3+T4, the fall minimum value computation unit 633 determines that the minimum value ΔTjmin of chip temperature fall in this power cycle is T3.

On the other hand, while the chip temperature is falling, as long as the chip temperature rises only within the range of the fall change threshold Y from the minimum value of the chip temperature in the current power cycle, the fall minimum value computation unit 633 determines that the chip temperature rise is within the error range. In this case, the fall minimum value computation unit 633 determines that the chip temperature has been falling, and updates the minimum value ΔTjmin of chip temperature fall in the current power cycle.

In this manner, the fall minimum value computation unit 633 computes the minimum value ΔTjmin of chip temperature fall based on the fall change threshold Y stored in the fall change threshold storage unit 634, and outputs the minimum value ΔTjmin to the fluctuation difference computation unit 635. This minimum value ΔTjmin of chip temperature fall is the peak value (minimal value) of chip temperature fall in the switching element.

The minimum value ΔTjmin of chip temperature fall is the minimum value of the temperature of the semiconductor chips 113A and 113B in one power cycle. The fall minimum value computation unit 633 computes the minimum value ΔTjmin of chip temperature fall in the semiconductor chip 113A and the minimum value ΔTjmin of chip temperature fall in the semiconductor chip 113B.

The fluctuation difference computation unit 635 computes a fluctuation difference in chip temperature. That is, the fluctuation difference computation unit 635 computes the temperature fluctuation difference ΔTj (max−min), which is the difference between ΔTjmax and ΔTjmin. The fluctuation difference computation unit 635 sends the temperature fluctuation difference ΔTj (max−min) to the number calculator 7.

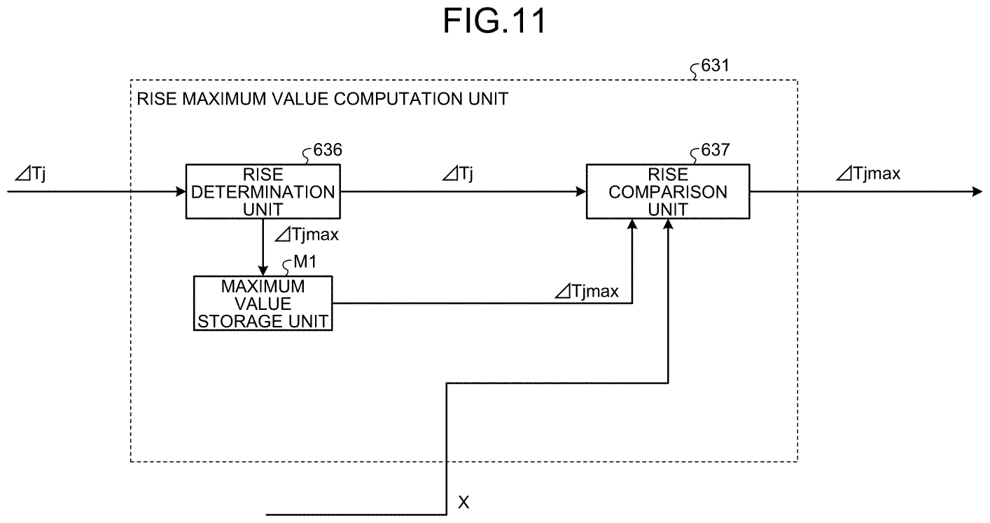

FIG. 11 is a diagram illustrating a configuration of the rise maximum value computation unit provided in the power conversion device according to the first embodiment. The rise maximum value computation unit 631 includes a rise determination unit 636, a rise comparison unit 637, and a maximum value storage unit M1.

The maximum value storage unit M1 stores the maximum value ΔTjmax of chip temperature rise sent from the rise determination unit 636. The rise determination unit 636 updates the maximum value ΔTjmax of chip temperature rise in the semiconductor chips 113A and 113B based on the chip temperature change ΔTj input from the chip temperature change calculator 62A. In response to determining that the newly input chip temperature change ΔTj is greater than the maximum value ΔTjmax of chip temperature rise stored in the maximum value storage unit M1, the rise determination unit 636 updates the maximum value ΔTjmax of chip temperature rise with the newly input value of the chip temperature change ΔTj. In this case, the rise determination unit 636 sends the chip temperature change ΔTj input from the chip temperature change calculator 62A to the rise comparison unit 637.

The rise comparison unit 637 computes ΔTjmax−X, which is the difference between the maximum value ΔTjmax of chip temperature rise stored in the maximum value storage unit M1 and the rise change threshold X input from the rise change threshold storage unit 632. The rise comparison unit 637 also determines whether ΔTj<ΔTjmax−X is satisfied, and in the case of ΔTj<ΔTjmax−X, outputs the maximum value ΔTjmax of chip temperature rise to the fluctuation difference computation unit 635. In the case of ΔTj≥ΔTjmax−X, the process of updating the maximum value ΔTjmax of chip temperature rise by the rise determination unit 636 is continued.

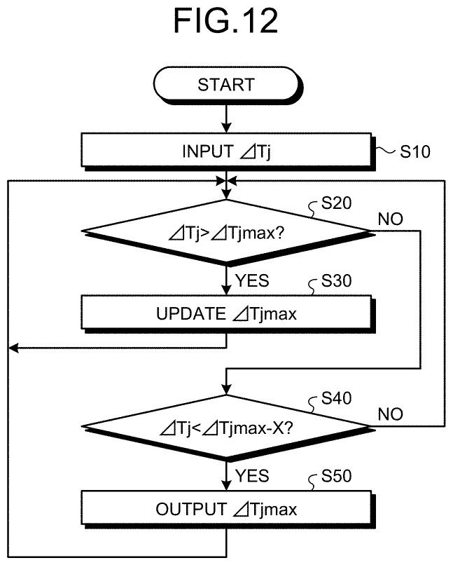

FIG. 12 is a flowchart illustrating a procedure for the operation of the rise maximum value computation unit provided in the power conversion device according to the first embodiment. The rise maximum value computation unit 631 receives the chip temperature change ΔTj from the chip temperature change calculator 62A, and inputs the chip temperature change ΔTj to the rise determination unit 636 (step S10).

The rise determination unit 636 compares the maximum value ΔTjmax of chip temperature rise stored in the maximum value storage unit M1 with the newly input chip temperature change ΔTj. The rise determination unit 636 determines whether ΔTj>ΔTjmax is satisfied (step S20). That is, the rise determination unit 636 determines whether the newly input chip temperature change ΔTj is a value greater than the stored maximum value ΔTjmax of chip temperature rise.

In response to the rise determination unit 636 determining that ΔTj>ΔTjmax is satisfied (step S20: Yes), the rise determination unit 636 updates the maximum value ΔTjmax of chip temperature rise with the newly input value of the chip temperature change ΔTj (step S30). In this case, the rise determination unit 636 stores the updated new maximum value ΔTjmax in the maximum value storage unit M1. After step S30, the rise maximum value computation unit 631 returns to step S20.

While ΔTj>ΔTjmax holds, the rise determination unit 636 continues to update the maximum value ΔTjmax. This means that when the chip temperature of the switching element is rising, the maximum value ΔTjmax of chip temperature rise is constantly updated with the input chip temperature change ΔTj.

In response to the rise determination unit 636 determining that ΔTj≤ΔTjmax is satisfied (step S20: No), the rise determination unit 636 inputs the input chip temperature change ΔTj to the rise comparison unit 637. That is, in response to determining that the newly input chip temperature change ΔTj is a value less than or equal to the maximum value ΔTjmax of chip temperature rise, the rise determination unit 636 inputs the chip temperature change ΔTj to the rise comparison unit 637.

The rise comparison unit 637 computes ΔTjmax−X, which is the difference between the maximum value ΔTjmax of chip temperature rise stored in the maximum value storage unit M1 and the rise change threshold X input from the rise change threshold storage unit 632. The rise comparison unit 637 compares ΔTjmax−X with the input chip temperature change ΔTj.

The rise comparison unit 637 determines whether ΔTj<ΔTjmax−X is satisfied (step S40). That is, the rise comparison unit 637 determines whether the input chip temperature change ΔTj is a value less than ΔTjmax−X.

In response to the rise comparison unit 637 determining that ΔTj≥ΔTjmax−X is satisfied (step S40: No), the rise maximum value computation unit 631 returns to step S20 and executes steps S20 to S40.

In response to the rise comparison unit 637 determining that ΔTj<ΔTjmax−X is satisfied (step S40: Yes), the rise comparison unit 637 outputs the current maximum value ΔTjmax of chip temperature rise to the fluctuation difference computation unit 635 (step S50).

In this manner, the rise maximum value computation unit 631 outputs ΔTjmax when the chip temperature change ΔTj input from the chip temperature change calculator 62A shows a decrease of more than the rise change threshold X from the maximum value ΔTjmax of chip temperature rise. Thereafter, the rise maximum value computation unit 631 returns to step S20 and repeats steps S20 to S50.

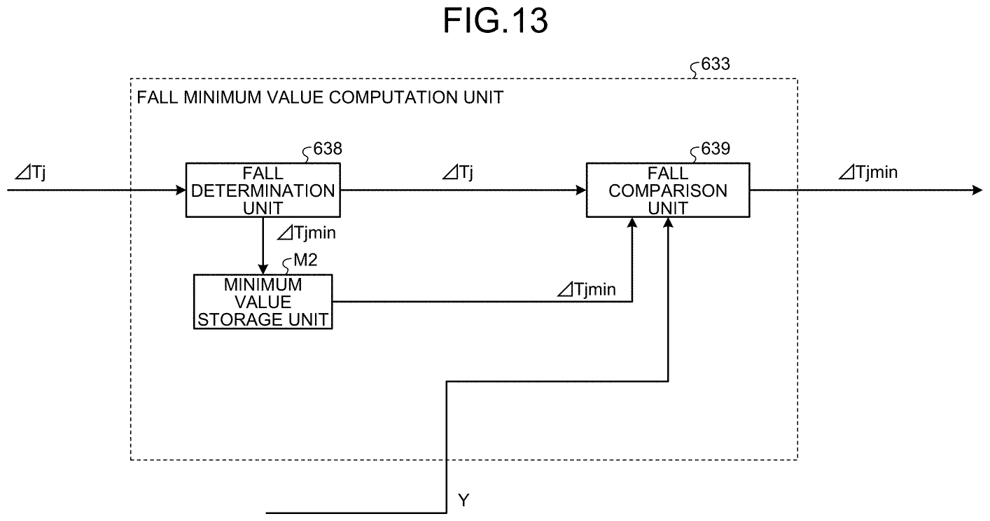

FIG. 13 is a diagram illustrating a configuration of the fall minimum value computation unit provided in the power conversion device according to the first embodiment. The fall minimum value computation unit 633 includes a fall determination unit 638, a fall comparison unit 639, and a minimum value storage unit M2.

The minimum value storage unit M2 stores the minimum value ΔTjmin of chip temperature fall sent from the fall determination unit 638. The fall determination unit 638 updates the minimum value ΔTjmin of chip temperature fall in the semiconductor chips 113A and 113B based on the chip temperature change ΔTj input from the chip temperature change calculator 62A. In response to determining that the newly input chip temperature change ΔTj is less than the stored minimum value ΔTjmin of chip temperature fall, the fall determination unit 638 updates the minimum value ΔTjmin of chip temperature fall with the newly input value of the chip temperature change ΔTj. In this case, the fall determination unit 638 sends the chip temperature change ΔTj input from the chip temperature change calculator 62A to the fall comparison unit 639.

The fall comparison unit 639 computes ΔTjmin+Y, which is the difference between the minimum value ΔTjmin of chip temperature fall stored in the minimum value storage unit M2 and the fall change threshold Y input from the fall change threshold storage unit 634. The fall comparison unit 639 also determines whether ΔTj>ΔTjmin+Y is satisfied, and in the case of ΔTj>ΔTjmin+Y, outputs the minimum value ΔTjmin of chip temperature fall to the fluctuation difference computation unit 635. In the case of ATj≤ΔTjmin+Y, the process of updating the minimum value ΔTjmin of chip temperature fall by the fall determination unit 638 is continued.

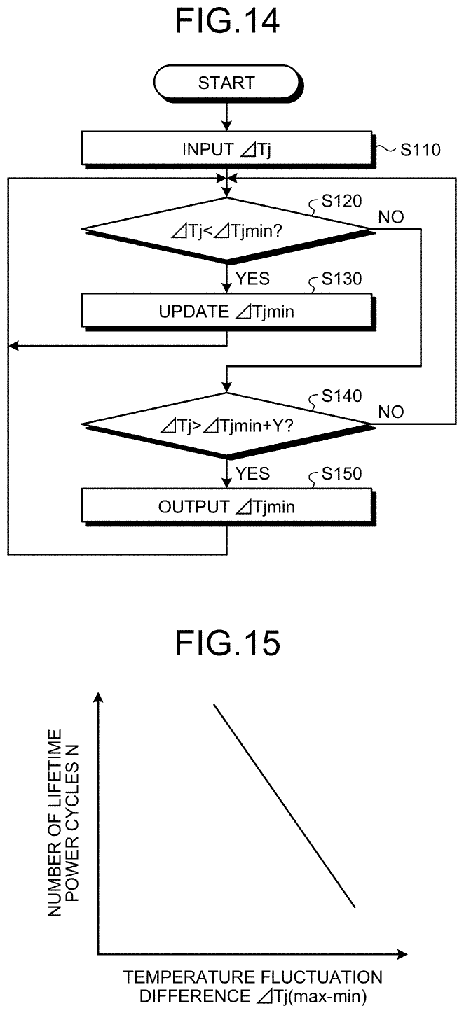

FIG. 14 is a flowchart illustrating a procedure for the operation of the fall minimum value computation unit provided in the power conversion device according to the first embodiment. The fall minimum value computation unit 633 receives the chip temperature change ΔTj from the chip temperature change calculator 62A, and inputs the chip temperature change ΔTj to the fall determination unit 638 (step S110).

The fall determination unit 638 compares the minimum value ΔTjmin of chip temperature fall stored in the minimum value storage unit M2 with the newly input chip temperature change ΔTj. The fall determination unit 638 determines whether ΔTj<ΔTjmin is satisfied (step S120). That is, the fall determination unit 638 determines whether the newly input chip temperature change ΔTj is a value less than the stored minimum value ΔTjmin of chip temperature fall.

In response to the fall determination unit 638 determining that ΔTj<ΔTjmin is satisfied (step S120: Yes), the fall determination unit 638 updates the minimum value ΔTjmin of chip temperature fall with the newly input value of the chip temperature change ΔTj (step S130). In this case, the fall determination unit 638 stores the updated new minimum value ΔTjmin in the minimum value storage unit M2. After step S130, the fall minimum value computation unit 633 returns to step S120.

While ΔTj<ΔTjmin holds, the fall determination unit 638 continues to update the minimum value ΔTjmin. This means that when the chip temperature of the switching element is falling, the minimum value ΔTjmin of chip temperature fall is constantly updated with the input chip temperature change ΔTj.

In response to the fall determination unit 638 determining that ΔTj≥ΔTjmin is satisfied (step S120: No), the fall determination unit 638 inputs the input chip temperature change ΔTj to the fall comparison unit 639. That is, in response to determining that the newly input chip temperature change ΔTj is a value less than or equal to the minimum value ΔTjmin of chip temperature fall, the fall determination unit 638 inputs the chip temperature change ΔTj to the fall comparison unit 639.

The fall comparison unit 639 computes ΔTjmin+Y, which is the sum of the minimum value ΔTjmin of chip temperature fall stored in the minimum value storage unit M2 and the fall change threshold Y input from the fall change threshold storage unit 634. The fall comparison unit 639 compares ΔTjmin+Y with the input chip temperature change ΔTj.

The fall comparison unit 639 determines whether ΔTj>ΔTjmin+Y is satisfied (step S140). That is, the fall comparison unit 639 determines whether the input chip temperature change ΔTj is a value greater than ΔTjmin+Y.

In response to the fall comparison unit 639 determining that ΔTjΔTjmin+Y is satisfied (step S140: No), the fall minimum value computation unit 633 returns to step S120 and executes steps S120 to S140.

In response to the fall comparison unit 639 determining that ΔTj>ΔTjmin+Y is satisfied (step S140: Yes), the fall comparison unit 639 outputs the current minimum value ΔTjmin of chip temperature fall to the fluctuation difference computation unit 635 (step S150).

In this manner, the fall minimum value computation unit 633 outputs ΔTjmin when the chip temperature change ΔTj input from the chip temperature change calculator 62A shows a rise of more than the fall change threshold Y from the minimum value ΔTjmin of chip temperature fall. Thereafter, the fall minimum value computation unit 633 returns to step S120 and repeats steps S120 to S150.

Note that in the temperature change calculator 63, the rise change threshold X and the fall change threshold Y may be the same value or different values.

Regarding the temperature fluctuation difference ΔTj (max−min) computed by the temperature change calculator 63, it is desirable that the rise change threshold X be set so as to exclude the range of chip temperature changes in which the degree of power cycle degradation L_{P/C} is so small that it has little influence on the life expected for the power conversion device 200A.

For example, consider switching elements having the same the power loss P_{Loss}: It is obvious that the switching element with a large thermal resistance undergoes larger fluctuations in the chip temperature change ΔTj than the switching element with a small thermal resistance. Therefore, any unintended noise present in the results of computation of switching element loss can lead to errors in the computed values of the temperature fluctuation difference ΔTj (max−min). Such errors may exert a large influence on the degree of power cycle degradation L_{P/C} over time, which can result in the false recognition that the power cycle life will end earlier than the life expected for the power conversion device 200A.

On the other hand, the power conversion device 200A according to the present embodiment uses the thresholds (rise change threshold X and fall change threshold Y) for the maximum value ΔTjmax of chip temperature rise and the minimum value ΔTjmin of chip temperature fall. Therefore, the power conversion device 200A does not compute the temperature fluctuation difference ΔTj (max−min) for any chip temperature change within the thresholds, and thus it is possible to prevent the above-described false recognition.

FIG. 15 is a schematic diagram for explaining the number of lifetime power cycles with respect to the temperature fluctuation difference of the switching element. FIG. 15 shows power cycle life data, i.e. the relationship between the temperature fluctuation difference ΔTj (max−min) of the switching element and the number of lifetime power cycles N. In FIG. 15, the horizontal axis represents the temperature fluctuation difference ΔTj (max−min), and the vertical axis represents the number of lifetime power cycles N.

As illustrated in FIG. 15, as the temperature fluctuation difference ΔTj (max−min) of the switching element increases, the number of lifetime power cycles N, which is the number of power cycles to fracture of the switching element, decreases.

The number calculator 7 retains the power cycle life data illustrated in FIG. 15, and computes the number of lifetime power cycles N corresponding to the temperature fluctuation difference ΔTj (max−min) using the power cycle life data. The number calculator 7 sends the number of lifetime power cycles N to the degradation degree calculator 8.

The number calculator 7 retains a data table of power cycle life data associated with each temperature change, for example, and converts the temperature fluctuation difference ΔTj (max−min) into the number of lifetime power cycles N for each temperature change. For example, the number calculator 7 retains a data table of power cycle life data indicating, for example, that N=B holds when temperature fluctuation difference ΔTj (max−min)=A, so that the number of lifetime power cycles N with respect to the computed temperature fluctuation difference ΔTj (max−min) can be obtained.

Note that the number calculator 7 may store an approximate expression for power cycle life data, and compute the number of lifetime power cycles N with respect to the temperature fluctuation difference ΔTj (max−min) using the approximate expression for power cycle life data. The approximate expression for power cycle life data is an expression that approximates the temperature fluctuation difference ΔTj (max−min) to the number of lifetime power cycles N.

A temperature change in the semiconductor chips 113A and 113B including the switching element causes shear strain at the bonding interface due to the difference between the linear expansion coefficient of the semiconductor chips 113A and 113B and the linear expansion coefficient of the wire 112. The crack in the bonding interface progresses due to repeated thermal stress on the semiconductor chips 113A and 113B; then part of the wire 112 is peeled off, and the current concentrates on the remaining part of the wire 112, causing the semiconductor chips 113A and 113B to deteriorate and break down. The larger the temperature rise during the use of the semiconductor chips 113A and 113B, the more shear strain applied to the bonding interface, accelerating the progress of power cycle degradation. Therefore, the level of power cycle degradation is determined by the temperature change of the semiconductor chips 113A and 113B and the number of cycles of the temperature change.

As an example, there is a method of determining whether the power conversion device is in an operating state or an idle state by comparing the current value of the input current to or the output current from the power conversion device with a threshold. With this method, the temperature fluctuation range of the switching element is estimated from the temperature rise value of the switching element in the operating state and the temperature fall value of the switching element in the idle state, and the degree of power cycle degradation is estimated from the temperature fluctuation range. In the case of this method, it is not possible to consider the temperature fluctuation in the case that the current increases from a value exceeding the threshold with the lapse of time and then returns to the initial value exceeding the threshold. Similarly, it is not possible to consider the temperature fluctuation in the case that the current decreases from a value below the threshold with the lapse of time and then returns to the initial value below the threshold. That is, temperature fluctuations that do not involve the threshold are ignored when considering power cycle degradation. This results in poor estimation accuracy of the degree of power cycle degradation. In this case, it is necessary to apply a switching element having a long power cycle life in anticipation of the power cycle degradation that cannot be considered, which causes an increase in the manufacturing cost of the power conversion device.

On the other hand, the power conversion device 200A according to the present embodiment estimates the degree of power cycle degradation L_{P/C} based on the temperature fluctuation difference ΔTj (max−min) in one power cycle, so that the degree of power cycle degradation L_{P/C} can be estimated accurately. Therefore, it is not necessary to apply a switching element having a power cycle life longer than necessary, and the manufacturing cost of the power conversion device 200A can be reduced.

Here, a modification of the power conversion device 200A according to the first embodiment will be described. In the power conversion device 200A, the place where the current measuring instrument 3A is connected is not limited to between the semiconductor module 1 and the motor 2.

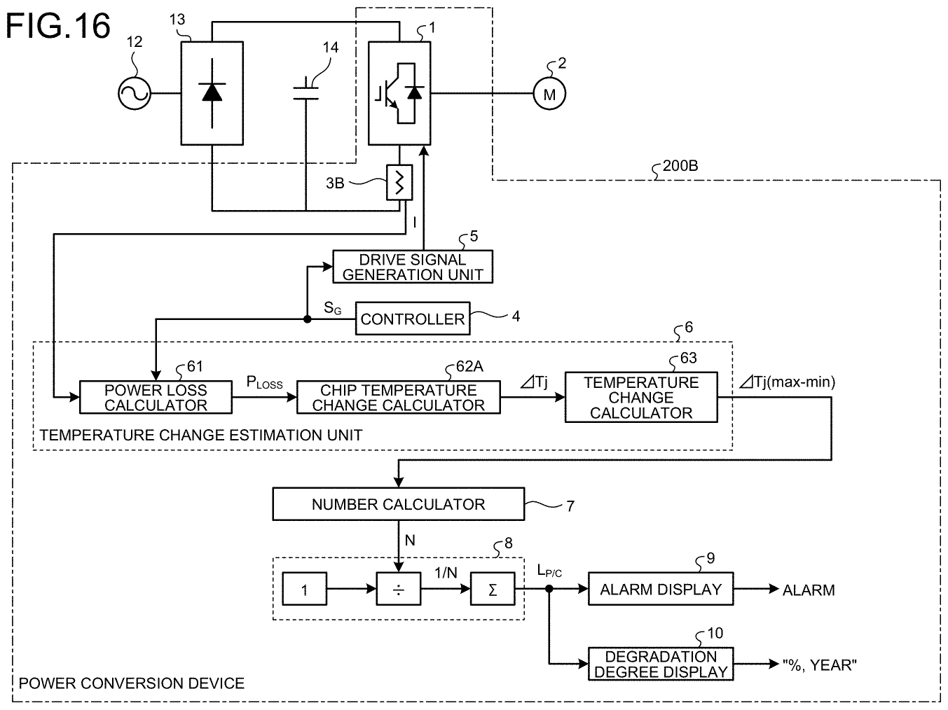

FIG. 16 is a diagram illustrating another exemplary configuration of the power conversion system including the power conversion device according to the first embodiment. Components in FIG. 16 that achieve the same functions as those of the power conversion device 200A illustrated in FIG. 3 are denoted by the same reference signs, and redundant descriptions are omitted.

In the power conversion device 200B, a current measuring instrument 3B is connected to the emitter side of the switching element on the lower side of the semiconductor module 1, thereby measuring the current flowing through the switching element. The current measuring instrument 3B is connected to the lower bus between the semiconductor module 1 and the converter circuit 13, and is connected to the temperature change estimation unit 6.

The power conversion device 200B differs from the power conversion device 200A only in the method of measuring the current, and uses similar methods to the power conversion device 200A to estimate a temperature change in the switching element and estimate the power cycle life, for example. Therefore, descriptions thereof are omitted.

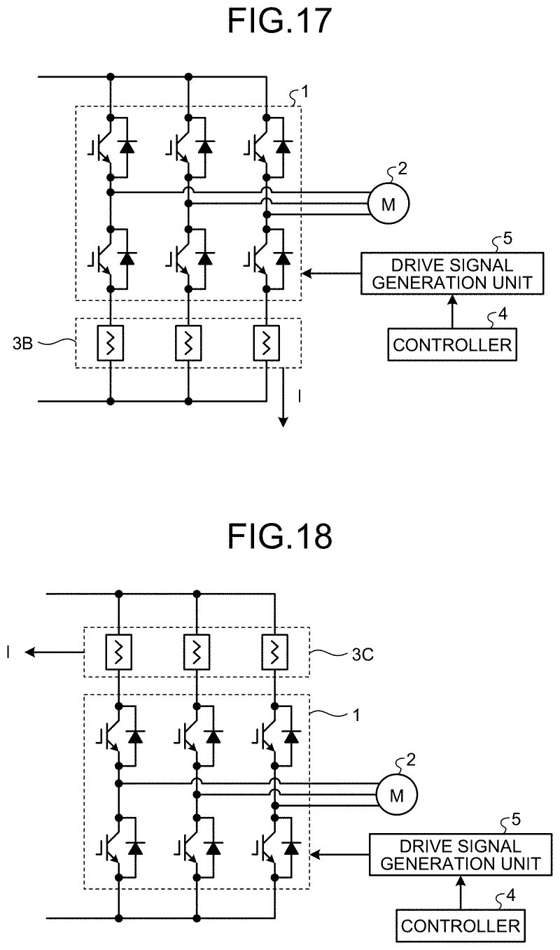

FIG. 17 is a diagram for explaining the connection position of the current measuring instrument provided in the power conversion device illustrated in FIG. 16. The semiconductor module 1 includes six switching elements. Each switching element includes an IGBT and a diode. Out of the six switching elements, the two switching elements at the right end constitute a first leg, the two switching elements located second from the right constitute a second leg, and the two switching elements at the left end constitute a third leg.

The current measuring instrument 3B includes three current measuring instruments. The first current measuring instrument of the current measuring instrument 3B is connected to the emitter side of the lower-arm switching element included in the first leg. The second current measuring instrument of the current measuring instrument 3B is connected to the emitter side of the lower-arm switching element included in the second leg. The third current measuring instrument of the current measuring instrument 3B is connected to the emitter side of the lower-arm switching element included in the third leg.

In the case where the current measuring instrument 3B is connected to the emitter side of the lower-arm switching element as illustrated in FIG. 17, the current flowing through the lower switching element can be measured, but the current flowing through the upper switching element cannot be directly measured. In the power conversion device 200B, the current flowing through the upper switching element can be estimated based on the magnitude of the current flowing through the lower switching element obtained by the current measuring instrument 3B, the switching pattern controlled by the controller 4, and the principle that the sum of the instantaneous values of the three phases of the three-phase alternating current is always zero.

Note that the current measuring instrument 3B may be connected to the collector side of the upper switching element. FIG. 18 is a diagram for explaining the connection position of the current measuring instrument connected to the collector side of the upper switching element of the semiconductor module provided in the power conversion device according to the first embodiment.

A current measuring instrument 3C includes three current measuring instruments. The first current measuring instrument of the current measuring instrument 3C is connected to the collector side of the upper-arm switching element included in the first leg. The second current measuring instrument of the current measuring instrument 3C is connected to the collector side of the upper-arm switching element included in the second leg. The third current measuring instrument of the current measuring instrument 3C is connected to the collector side of the upper-arm switching element included in the third leg.

In the case where the current measuring instrument 3C is connected to the collector side of the upper-arm switching element as illustrated in FIG. 18, the current flowing through the upper switching element can be measured, but the current flowing through the lower switching element cannot be directly measured. In the power conversion device 200B including the current measuring instrument 3C, the current flowing through the lower switching element can be estimated based on the magnitude of the current flowing through the upper switching element obtained by the current measuring instrument 3C, the switching pattern controlled by the controller 4, and the principle that the sum of the instantaneous values of the three phases of the three-phase alternating current is always zero.

As described above, in the first embodiment, the power conversion device 200A sets the maximum value ΔTjmax of chip temperature rise based on the rise change threshold X, and sets the minimum value ΔTjmin of chip temperature fall based on the fall change threshold Y. Consequently, the power conversion device 200A can detect temperature fluctuations without depending on changes in current value during operation or the output frequency of the power conversion device 200A. Therefore, the power conversion device 200A can accurately estimate the degree of power cycle degradation L_{P/C}. Thus, the power conversion device 200A can accurately estimate the life of the switching element; therefore, it is possible to provide the power conversion device 200A that is highly reliable.

In addition, even with different current measurement positions such as those illustrated in FIGS. 17 and 18, the degree of power cycle degradation L_{P/C} can be estimated with high accuracy regardless of the status of operation.

### Second Embodiment

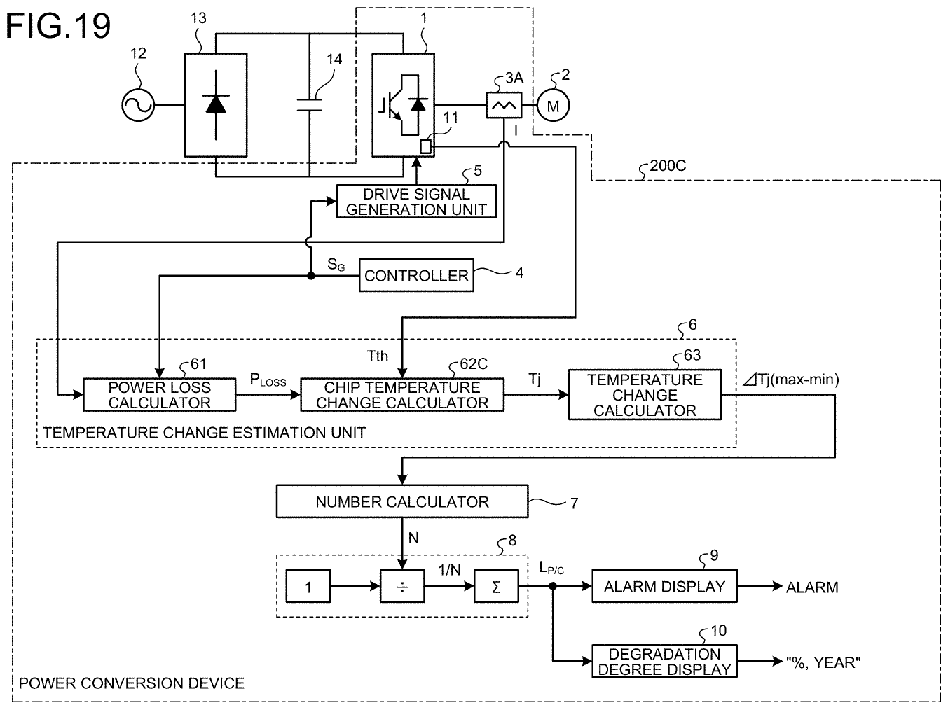

Next, a second embodiment of the present invention will be described with reference to FIGS. 19 to 21. In the second embodiment, the degree of power cycle degradation L_{P/C} is estimated using the reference temperature of the semiconductor module 1.

FIG. 19 is a diagram illustrating a configuration of a power conversion system including a power conversion device according to the second embodiment. Components in FIG. 19 that achieve the same functions as those of the power conversion device 200A illustrated in FIG. 3 are denoted by the same reference signs, and redundant descriptions are omitted.

The power conversion system according to the second embodiment includes the commercial power supply 12, the converter circuit 13, the smoothing capacitor 14, a power conversion device 200C, and the motor 2. The power conversion device 200C includes a reference temperature measuring instrument 11 that measures a reference temperature Tth of the semiconductor module 1, in addition to the components provided in the power conversion device 200A. In addition, the temperature change estimation unit 6 includes the power loss calculator 61, a chip temperature change calculator 62C, and the temperature change calculator 63. The chip temperature change calculator 62C is connected to the power loss calculator 61 and the temperature change calculator 63.

The reference temperature measuring instrument 11 measures the reference temperature Tth of the semiconductor module 1, and outputs the measured reference temperature Tth to the chip temperature change calculator 62C.

For example, in a case where the power converter is operated at low frequency, fluctuation can occur in the ambient temperature of the semiconductor chip including the switching element during the computation of the temperature fluctuation difference ΔTj (max−min), and affect the temperature fluctuation difference ΔTj (max−min). There is a case in which the base temperature of the switching element rises while the chip temperature is rising, and then the base temperature of the switching element does not fall due to some other influence while the chip temperature is falling. In this case, because the increase in the base temperature is not taken into consideration, the power conversion device computes the temperature fluctuation difference ΔTj (max−min) that is excessive.

Therefore, in the present embodiment, the power conversion device 200C computes the temperature fluctuation difference ΔTj (max−min) in consideration of temperature changes other than those in the semiconductor chips 113A and 113B including the switching element.

Specifically, the power conversion device 200C measures a criterial temperature (reference temperature Tth of the semiconductor module 1) in advance, estimates the junction temperature of the semiconductor chips 113A and 113B from the reference temperature Tth and a chip temperature change, and computes the temperature fluctuation difference ΔTj (max−min). Consequently, the power conversion device 200C can accurately estimate the temperature of the switching element.

The reference temperature Tth measured by the reference temperature measuring instrument 11 is the substrate temperature in the semiconductor module 1 or the temperature of the base plate 115. Therefore, the reference temperature measuring instrument 11 is located on the bottom surface of the semiconductor chips 113A and 113B, the upper surface of the base plate 115, or the like.

Note that the power conversion device 200C may measure the temperature of the base plate 115 by attaching a cooler (cooling fin) to the semiconductor module 1 and measuring the temperature of the cooler.

The reference temperature measuring instrument 11 may have any configuration as long as it is configured to measure the reference temperature Tth. For example, the reference temperature measuring instrument 11 may include a thermistor, an optical system temperature sensor, or the like.

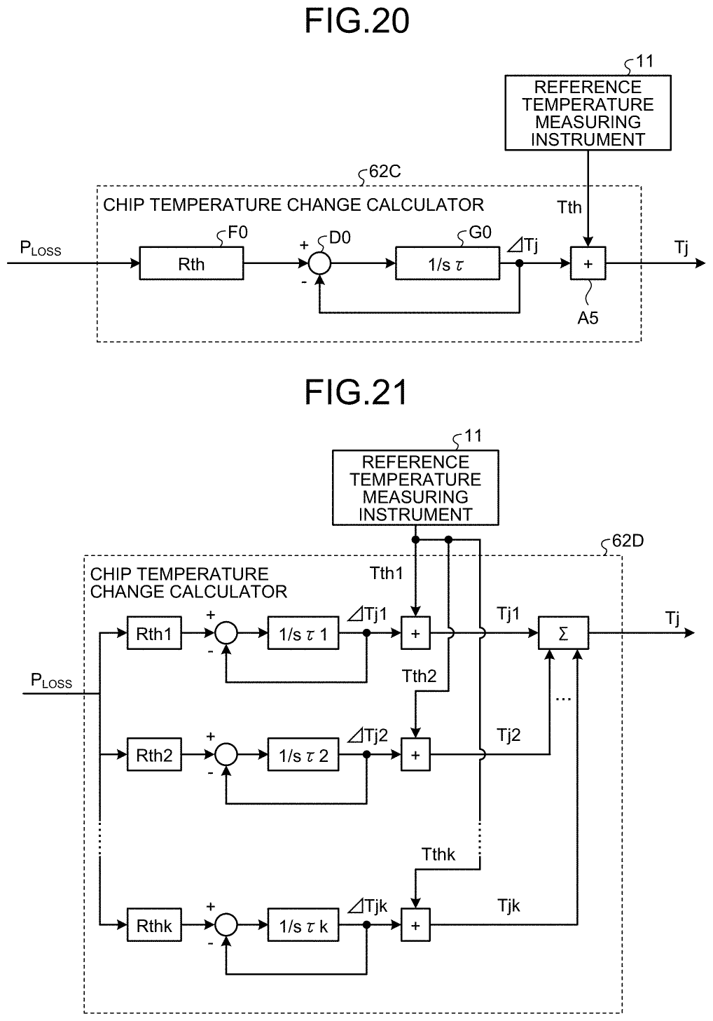

FIG. 20 is a diagram illustrating a configuration of the chip temperature change calculator provided in the power conversion device according to the second embodiment. Components in FIG. 20 that achieve the same functions as those of the chip temperature change calculator 62A illustrated in FIG. 8 are denoted by the same reference signs, and redundant descriptions are omitted.

In a similar manner to the chip temperature change calculator 62A according to the first embodiment, the chip temperature change calculator 62C computes the chip temperature change ΔTj based on the power loss P_{Loss} input from the power loss calculator 61.

The chip temperature change calculator 62C adds the reference temperature Tth input from the reference temperature measuring instrument 11 to the chip temperature change ΔTj computed using the power loss P_{Loss} and the transient thermal resistance Rth(t). The chip temperature change calculator 62C outputs the result of the addition of the reference temperature Tth to the chip temperature change ΔTj as a chip temperature Tj to the temperature change calculator 63.

FIG. 21 is a diagram illustrating another exemplary configuration of the chip temperature change calculator provided in the power conversion device according to the second embodiment. Components in FIG. 21 that achieve the same functions as those of the chip temperature change calculator 62B illustrated in FIG. 9 are denoted by the same reference signs, and redundant descriptions are omitted.

The temperature change estimation unit 6 may include a chip temperature change calculator 62D, instead of the chip temperature change calculator 62C. FIG. 21 illustrates the configuration of the chip temperature change calculator 62D to be applied for high-accuracy simulation of the transient thermal resistance Rth(t).

In a similar manner to the chip temperature change calculator 62B according to the first embodiment, the chip temperature change calculator 62D expresses the transient thermal resistance Rth(t) by the sum of a plurality of heat transfer functions of a plurality of first-order lag systems. The chip temperature change calculator 62D adds the reference temperature Tth input from the reference temperature measuring instrument 11 to the chip temperature change ΔTj computed using the power loss P_{Loss} and the transient thermal resistance Rth(t). The chip temperature change calculator 62D outputs the result of the addition of the reference temperature Tth to the chip temperature change ΔTj as the chip temperature Tj to the temperature change calculator 63.

In the first embodiment, the temperature change calculator 63 computes the temperature fluctuation difference ΔTj (max−min) of the switching element based on the chip temperature change ΔTj, whereas the temperature change calculator 63 in the second embodiment computes the temperature fluctuation difference ΔTj (max−min) of the switching element based on the chip temperature Tj. The temperature change calculator 63 according to the second embodiment computes the temperature fluctuation difference ΔTj (max−min) through similar processing to the temperature change calculator 63 according to the first embodiment.

The number calculator 7, the degradation degree calculator 8, the alarm display 9, and the degradation degree display 10 in the power conversion device 200C execute similar processing to the number calculator 7, the degradation degree calculator 8, the alarm display 9, and the degradation degree display 10 in the power conversion device 200A.

As described above, in the second embodiment, the power conversion device 200C estimates the degree of power cycle degradation L_{P/C} in consideration of the reference temperature Tth, and thus can estimate the degree of power cycle degradation L_{P/C} more accurately than the power conversion device 200A.

### Third Embodiment

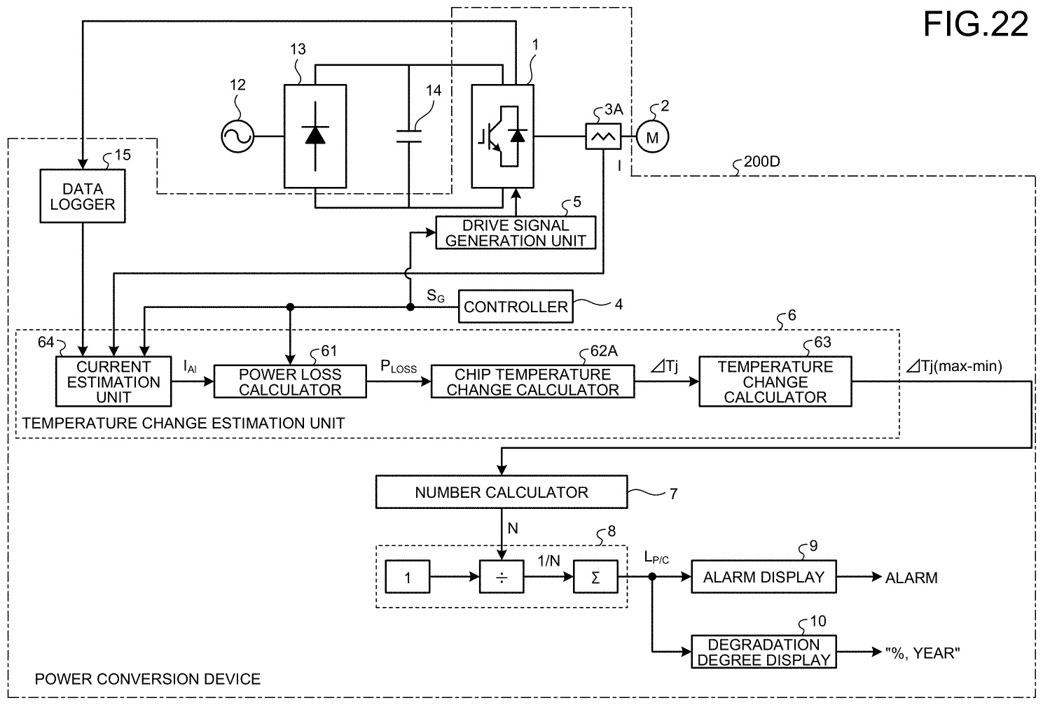

Next, a third embodiment of the present invention will be described with reference to FIGS. 22 to 26. In the third embodiment, an actual current value is obtained by removing the influence of noise from the current value I measured by the current measuring instrument 3A and learned, and the degree of power cycle degradation L_{P/C} is estimated using the learned actual current value.

FIG. 22 is a diagram illustrating a configuration of a power conversion system including a power conversion device according to the third embodiment. Components in FIG. 22 that achieve the same functions as those of the power conversion device 200A illustrated in FIG. 3 are denoted by the same reference signs, and redundant descriptions are omitted.

The power conversion system according to the third embodiment includes the commercial power supply 12, the converter circuit 13, the smoothing capacitor 14, a power conversion device 200D, and the motor 2. The power conversion device 200D includes a data logger 15 in addition to the components provided in the power conversion device 200A. In addition, the temperature change estimation unit 6 includes the power loss calculator 61, the chip temperature change calculator 62A, the temperature change calculator 63, and a current estimation unit 64.

The data logger 15 is an example of a measuring instrument that measures the actual current waveform flowing through the switching element. The data logger 15 sends the measured actual current waveform to the current estimation unit 64. Note that the data logger 15 may be configured separately from the power conversion device 200D.

In the power conversion device 200D, the current value I measured by the current measuring instrument 3A is sent to the current estimation unit 64. In addition, the controller 4 sends the control signal S_{G} to the drive signal generation unit 5, the power loss calculator 61, and the current estimation unit 64.

Based on the current value I measured by the current measuring instrument 3A and the control signal S_{G} input from the controller 4, the current estimation unit 64 removes the influence of noise from the current value I to obtain an actual current value I_{AI} for output.

For example, in a case where the power converter is operated at low current, noise can be superimposed on the current value I measured by the current measuring instrument 3A, and cause an error in the computation of the power loss P_{Loss} by the power loss calculator 61. Such an error in the computation of the power loss P_{Loss} results in reduced estimation accuracy of the degree of power cycle degradation L_{P/C}.

Therefore, in the present embodiment, the power conversion device 200D computes the noise superimposed on the current value I, learns the actual current value I_{AI} without noise, and estimates the degree of power cycle degradation L_{P/C} using the actual current value I_{AI}.

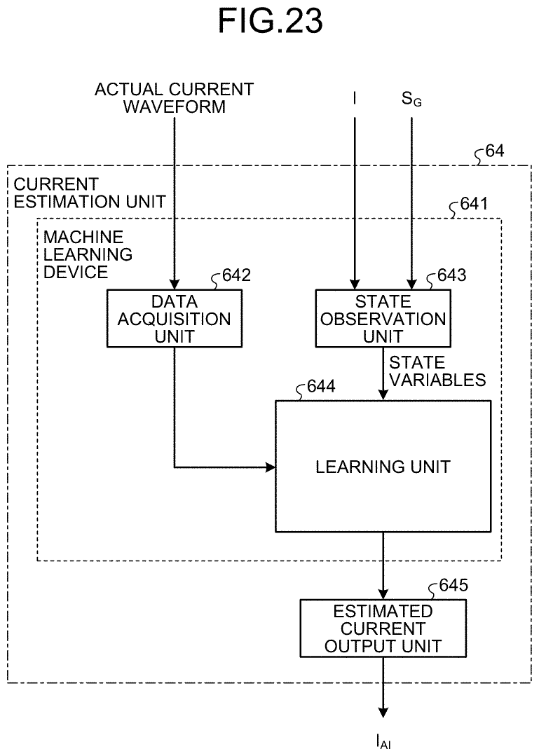

FIG. 23 is a diagram illustrating a configuration of the current estimation unit provided in the power conversion device according to the third embodiment. The current estimation unit 64 includes a machine learning device 641 and an estimated current output unit 645. The machine learning device 641 includes a data acquisition unit 642, a state observation unit 643, and a learning unit 644.

The state observation unit 643 observes the current value I output from the current measuring instrument 3A and the control signal S_{G} output from the controller 4 as state variables, and outputs the state variables to the learning unit 644. In the learning stage, the data acquisition unit 642 acquires the actual current waveform of the current flowing through the switching element from a current detection device such as the data logger 15, and outputs the actual current waveform to the learning unit 644.

The actual current waveform in the learning stage refers to a pure current waveform with no noise superimposed. An example of the actual current waveform in the learning stage is the current waveform measured by opening the semiconductor module 1 and directly attaching a current detection device to the switching element.

The learning unit 644 learns a computation model for computing the actual current value I_{AI} corresponding to the current value I based on the data set created based on the combination of the state variables output from the state observation unit 643 and the actual current waveform output from the data acquisition unit 642. The data set is data in which the state variables and the actual current waveform (determination data) are associated with each other. The state variables output from the state observation unit 643 are the current value I output from the current measuring instrument 3A and the control signal S_{G} output from the controller 4.

In the utilization stage, the estimated current output unit 645 receives the current value I and the control signal S_{G} output from the state observation unit 643 via the learning unit 644, computes the actual current value I_{AI} using the computation model, which is the learning model learned by the learning unit 644, and then outputs the actual current value I_{AI} to the power loss calculator 61.

The actual current value I_{AI} output from the estimated current output unit 645 to the power loss calculator 61 corresponds to the current value I (current value I output from the current measuring instrument 3A) in the first and second embodiments. That is, the actual current value I_{AI} is a current value that the power loss calculator 61 uses to calculate the power loss P_{Loss}.

The current estimation unit 64 learns a computation model for computing the actual current value I_{AI} in the learning stage, and computes the actual current value I_{AI} using the computation model in the utilization stage. Consequently, the current estimation unit 64 learns the actual current value I_{AI} without noise for use in estimating the degree of power cycle degradation L_{PG}.

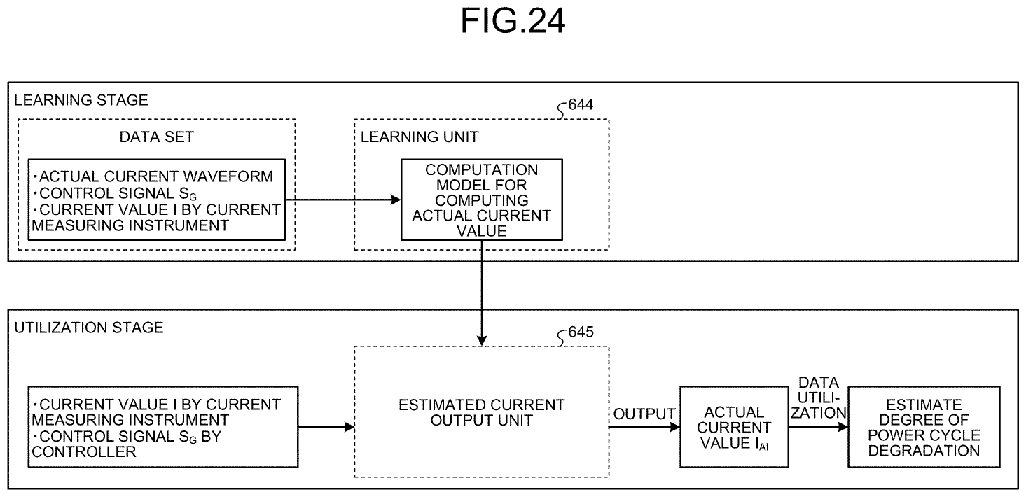

FIG. 24 is a diagram for explaining a procedure for learning processing and utilization processing by the power conversion device according to the third embodiment. The current estimation unit 64 performs the processing of learning a computation model in the learning stage, and performs the processing of computing the actual current value I_{AI} in the utilization stage.

(Learning Stage)

The data acquisition unit 642 acquires the actual current waveform of the current flowing through the switching element from a current detection device such as the data logger 15. In addition, the state observation unit 643 observes the current value I output from the current measuring instrument 3A and the control signal S_{G} output from the controller 4 as state variables. The learning unit 644 learns a computation model for computing the actual current value I_{AI} based on the data set created based on the combination of the state variables output from the state observation unit 643 and the actual current waveform output from the data acquisition unit 642.

(Utilization Stage)

The current estimation unit 64 computes the actual current value I_{AI} using the computation model learned by the learning unit 644. Specifically, the current estimation unit 64 computes the actual current value I_{AI} by inputting the current value I output from the current measuring instrument 3A and the control signal S_{G} output from the controller 4 to the computation model. The power conversion device 200D estimates the degree of power cycle degradation L_{P/C} using the actual current value I_{AI}.

Note that the machine learning device 641 is not necessarily provided in the power conversion device 200D, and may be provided outside the power conversion device 200D. The machine learning device 641 may be provided in a device connectable to the power conversion device 200D via a network. That is, the machine learning device 641 may be a separate component connected to the power conversion device 200D via a network. Alternatively, the machine learning device 641 may exist on a cloud server.

The learning unit 644 learns the actual current value I_{AI} corresponding to the current value I through what is called supervised learning according to, for example, a neural network model. Here, supervised learning refers to a model that provides a large number of input-result (label) data pairs to a learning device to learn features in those data sets and estimate results from inputs.

A neural network includes an input layer composed of a plurality of neurons, an intermediate layer (hidden layer) composed of a plurality of neurons, and an output layer composed of a plurality of neurons. The number of intermediate layers may be one, or may be two or more.

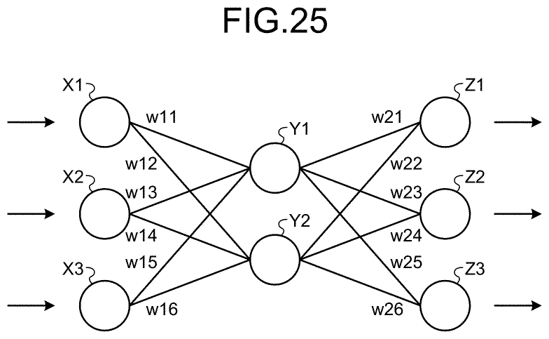

FIG. 25 is a diagram illustrating a configuration of a neural network that is used by the machine learning device according to the third embodiment. For example, in the three-layer neural network illustrated in FIG. 25, a plurality of inputs are input to input layers X1 to X3, then the values thereof are multiplied by weights w11 to w16 and input to intermediate layers Y1 and Y2, and the results thereof are further multiplied by weights w21 to w26 and output from output layers Z1 to Z3. The output results vary depending on the values of the weights w11 to w16 and the weights w21 to w26.

The neural network according to the third embodiment learns the actual current value I_{AI} through what is called supervised learning according to the data set created based on the combination of the current value I and the control signal S_{G} observed by the state observation unit 643 and the actual current waveform acquired by the data acquisition unit 642.

Specifically, the neural network learns the actual current value I_{AI} by adjusting the weights w11 to w16 and w21 to w26 such that outputs from the output layers Z1 to Z3 in response to inputs of the current value I and the control signal S_{G} to the input layers X1 to X3 approach the actual current waveform. The learning unit 644 sends the neural network with the adjusted weights w11 to w16 and w21 to w26 to the estimated current output unit 645.

The learning unit 644 may learn the actual current value I_{AI} according to the data sets created for a plurality of power conversion devices. The learning unit 644 may learn the actual current value I_{AI} by acquiring data sets from a plurality of power conversion devices used at the same site or by using the data sets collected from a plurality of power conversion devices operating independently at different sites. Further, it is possible to add a new power conversion device to a list of power conversion devices from which data sets are collected or to remove some power conversion device from the list during processing. In addition, a machine learning device that has learned the actual current value I_{AI} for some power conversion device may be attached to a different power conversion device, and the actual current value I_{AI} may be relearned and updated for the different power conversion device.

A learning algorithm for use in the learning unit 644 can be deep learning, which learns feature extraction directly. Alternatively, other known methods such as genetic programming, functional logic programming, and support vector machines, for example, can be used to execute machine learning.

The current estimation unit 64 outputs the actual current value I_{AI} computed using the computation model to the power loss calculator 61. The power loss calculator 61 calculates the power loss P_{Loss} generated in the switching element based on the actual current value I_{AI} acquired from the current estimation unit 64 and the control signal S_{G} input from the controller 4. Thereafter, the power conversion device 200D estimates the degree of power cycle degradation L_{P/C} according to the procedure described in the first embodiment. Note that the current estimation unit 64 may be applied to the power conversion devices 200A, 200B, and 200C.

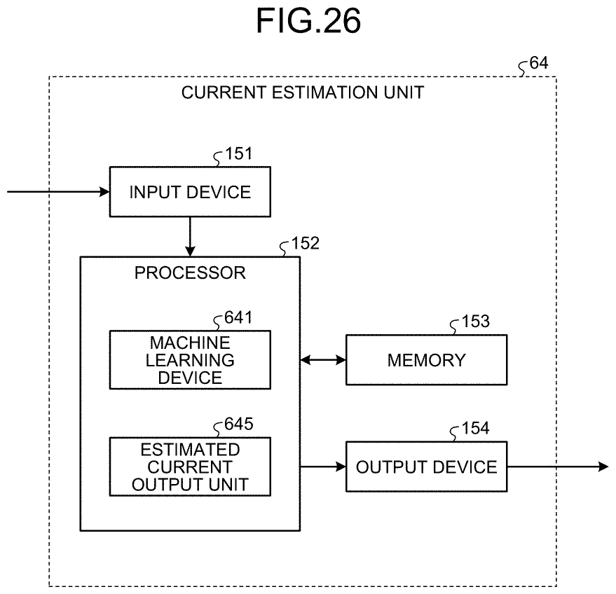

Here, the hardware configuration of the current estimation unit 64 will be described. FIG. 26 is a diagram illustrating an exemplary hardware configuration that implements the current estimation unit provided in the power conversion device according to the third embodiment.

The current estimation unit 64 can be implemented by an input device 151, a processor 152, a memory 153, and an output device 154. The processor 152 is exemplified by a central processing unit (CPU, also referred to as a central processing device, a processing device, a computation device, a microprocessor, a microcomputer, a processor, or a digital signal processor (DSP)), or a system large scale integration (LSI). The memory 153 is exemplified by a random access memory (RAM) or a read only memory (ROM).

The current estimation unit 64 is implemented by the processor 152 reading and executing a computer-executable learning program for the actual current value I_{AI} stored in the memory 153 for executing the operation of the current estimation unit 64. It can also be said that the learning program that is a program for executing the operation of the current estimation unit 64 causes a computer to execute the procedure or method related to the current estimation unit 64.

The learning program to be executed by the current estimation unit 64 has a module configuration including the machine learning device 641 and the estimated current output unit 645, which are loaded on a main storage device and generated on the main storage device.

The input device 151 receives the current value I, the control signal S_{G}, the actual current waveform, and the like for transmission to the processor 152. The memory 153 is also used as a temporary memory when the processor 152 executes various processes. The memory 153 stores, for example, the learning program, the current value I, the control signal S_{G}, the actual current waveform, and the like. The output device 154 outputs the actual current value I_{AI} to the power loss calculator 61.

The learning program may be stored in a computer-readable storage medium in an installable or executable file and provided as a computer program product. Alternatively, the learning program may be provided to the current estimation unit 64 via a network such as the Internet.

Note that a part of the function of the current estimation unit 64 may be implemented by dedicated hardware such as a dedicated circuit, and the other part may be implemented by software or firmware. In addition, the power conversion devices 200A to 200C may be partially configured by the hardware of FIG. 26.

As described above, in the third embodiment, the current estimation unit 64 learns the actual current value I_{AI} corresponding to the current value I based on the current value I, the control signal S_{G}, and the actual current waveform, and the power conversion device 200D estimates the degree of power cycle degradation L_{P/C} using the actual current value I_{AI} in which the influence of noise in the current value I is reduced. Consequently, it is possible to estimate the degree of power cycle degradation L_{P/C} in which the influence of noise in the current value I is reduced.

The configurations described in the above-mentioned embodiments indicate examples of the contents of the present invention. The configurations can be combined with another well-known technique, and some of the configurations can be omitted or changed in a range not departing from the gist of the present invention.

### REFERENCE SIGNS LIST

1 semiconductor module; 2 motor; 3A to 3C current measuring instrument; 4 controller; 5 drive signal generation unit; 6 temperature change estimation unit; 7 number calculator; 8 degradation degree calculator; 9 alarm display; 10 degradation degree display; 11 reference temperature measuring instrument; 12 commercial power supply; 13 converter circuit; 14 smoothing capacitor; 15 data logger; 61 power loss calculator; 62A to 62D chip temperature change calculator; 63 temperature change calculator; 64 current estimation unit; 111 circuit pattern; 112 wire; 113A, 113B semiconductor chip; 114 substrate; 115 base plate; 151 input device; 152 processor; 153 memory; 154 output device; 200A to 200D power conversion device; 611 IGBT loss calculator; 612 FWD loss calculator; 613 signal analyzer; 614 IGBT steady loss data table; 615 IGBT on loss data table; 616 IGBT off loss data table; 617 FWD steady loss data table; 618 FWD recovery loss data table; 631 rise maximum value computation unit; 632 rise change threshold storage unit; 633 fall minimum value computation unit; 634 fall change threshold storage unit; 635 fluctuation difference computation unit; 636 rise determination unit; 637 rise comparison unit; 638 fall determination unit; 639 fall comparison unit; 641 machine learning device; 642 data acquisition unit; 643 state observation unit; 644 learning unit; 645 estimated current output unit; A1, A2 adder; M1 maximum value storage unit; M2 minimum value storage unit; P1 to P5 calculator.

1. A power conversion device including a switching element, the power conversion device comprising:
control circuitry to output a control signal to control the switching element;
drive circuitry to drive the switching element based on the control signal;
a temperature change estimator to estimate a temperature change in a semiconductor chip containing the switching element based on a current value flowing through the switching element and the control signal;
a number calculator to calculate, based on the temperature change, the number of power cycles to fracture of the semiconductor chip due to repeated power cycles, where one power cycle is a rise and a fall in a temperature of the semiconductor chip; and
a degradation degree calculator to compute, based on the number of power cycles to fracture, a degree of degradation of the semiconductor chip caused by the repeated power cycles as a degree of power cycle degradation, wherein
the temperature change estimator calculates a maximum value of a temperature of the semiconductor chip in the one power cycle based on a first threshold and the temperature change, the first threshold being a threshold of temperature fall allowed when it is determined that the temperature of the semiconductor chip is rising, calculates a minimum value of the temperature of the semiconductor chip in the one power cycle based on a second threshold and the temperature change, the second threshold being a threshold of temperature rise allowed when it is determined that the temperature of the semiconductor chip is falling, and calculates a temperature fluctuation difference in the one power cycle of the semiconductor chip based on the maximum value and the minimum value,
the number calculator calculates the number of power cycles to fracture based on the temperature fluctuation difference,
the temperature change estimator calculates a power loss generated in the switching element based on the current value flowing through the switching element and the control signal, and calculates the temperature change based on a transient thermal resistance of the switching element and the power loss, the transient thermal resistance being computed from transient thermal resistance data indicating temporal changes in a thermal resistance value of the switching element and data of a first-order lag term in which a thermal time constant of the switching element is used, and
the transient thermal resistance is expressed by a sum of a plurality of heat transfer functions of a plurality of first-order lag systems.

2. (canceled)

3. The power conversion device according to claim 1, further comprising
a current measuring instrument to measure the current value flowing through the switching element, wherein
the temperature change estimator includes a current estimator to estimate an actual current value from the current value flowing through the switching element, the actual current value being a current value with no noise superimposed,
the current estimator includes:
a machine learning device to learn a computation model for computing the actual current value from the current value flowing through the switching element; and
estimated current output circuitry to estimate the actual current value based on a result of learning by the machine learning device,
the machine learning device includes:
state observation circuitry to observe, as state variables, the control signal and the current value measured by the current measuring instrument;
data acquisition circuitry to acquire a current waveform actually flowing through the switching element; and
learning circuitry to learn the actual current value corresponding to the current value flowing through the switching element according to a data set created based on a combination of the state variables and the current waveform, and
the temperature change estimator estimates the temperature change using the actual current value learned by the learning circuitry as the current value flowing through the switching element.

4. The power conversion device according to claim 1, wherein
the temperature change estimator calculates, based on the control signal, a switching frequency of the switching element and a duty ratio of switching of the switching element, and
the temperature change estimator calculates the power loss based on the current value flowing through the switching element, a loss characteristic of the switching element corresponding to the current value flowing through the switching element, the switching frequency, and the duty ratio.

5.-6. (canceled)

7. The power conversion device according to claim 4, wherein
the number calculator calculates the number of power cycles to fracture based on power cycle life data and the temperature fluctuation difference, the power cycle life data indicating a correspondence relationship between the temperature fluctuation difference and the number of power cycles to fracture.

8. The power conversion device according to claim 1, further comprising
a reference temperature measuring instrument to measure a temperature of a semiconductor module containing the semiconductor chip as a reference temperature of the semiconductor chip serving as a criterion, wherein
the temperature change estimator adds the reference temperature to estimate the temperature change.

9. The power conversion device according to claim 1, wherein
the switching element is an insulated gate bipolar transistor and a freewheel diode,
the semiconductor chip includes a first chip containing the insulated gate bipolar transistor and a second chip containing the freewheel diode,
the temperature change estimator separately calculates a temperature change in the first chip and a temperature change in the second chip,
the number calculator separately calculates the number of power cycles to fracture of the first chip and the number of power cycles to fracture of the second chip, and
the degradation degree calculator separately calculates a degree of degradation of the first chip and a degree of degradation of the second chip.

10. The power conversion device according to claim 1, further comprising:
an alarm display to display an alarm when the degree of power cycle degradation exceeds a reference value; and
a degradation degree display to display the degree of power cycle degradation.

11. A machine learning device comprising:
state observation circuitry to observe, as state variables, a control signal output from control circuitry that controls a switching element and a current value measured by a current measuring instrument that measures a current value flowing through the switching element;
data acquisition circuitry to acquire a current waveform actually flowing through the switching element; and
learning circuitry to learn an actual current value from the current value flowing through the switching element according to a data set created based on a combination of the state variables and the current waveform, the actual current value being a current value with no noise superimposed.
